(19) United States
(12) Patent Application Publication
(10) Pub. No.: US 2010/0275976 A1
(43) Pub. Date: Nov. 4, 2010

(54) PHOTOVOLTAIC MODULE WITH EDGE ACCESS TO PV STRINGS, INTERCONNECTION METHOD, APPARATUS, AND SYSTEM

(75) Inventors: Leonid Borisovich Rubin, Burnaby (CA); Valery Michailovich Nebusov, Burnaby (CA)

Correspondence Address: KNOBBE MARTENS OLSON & BEAR LLP, 2040 MAIN STREET, FOURTEENTH FLOOR, IRVINE, CA, 92614, US

(73) Assignee: DAY4 ENERGY INC., Burnaby, BC (CA)

(21) Appl. No.: 12/809,525

(22) PCT Filed: Dec. 18, 2007
(86) PCT No.: PCT/CA2007/002301

§ 371 Date: Jul. 26, 2010

(51) Int. Cl. H01L 31/048; H01R 13/60; H01M 6/00

(52) U.S. Cl. 136/251; 439/527; 29/623.1

(57) ABSTRACT

A photovoltaic module apparatus includes PV cells arranged in a planar array, the PV cells being electrically connected in at least one string having positive and negative terminals. Positive and negative conductors are connected to the positive and negative terminals respectively and front and back encapsulating sheets are disposed on the front and back sides of the array to form a sub-laminate. Each of the positive and negative conductors has a respective portion extending from the positive and negative terminals, between the front and back encapsulating sheets. Front and back protectors are disposed on the front and back encapsulating sheets to form a laminate. First and second terminating portions of the positive and negative conductors extend outwardly from the outer perimeter edge of the laminate. A frame including a frame member having a holder may be provided about at least one portion of the outer perimeter edge of the laminate.

### BACKGROUND OF THE INVENTION

This invention relates to photovoltaic (PV) modules and more particularly to configuring PV cells within a PV module to permit conductors associated with a string or strings of PV cells to extend from a perimeter edge of the PV module in which they are installed.

The design and production of PV modules comprised of crystalline silicon PV cells has remained virtually unchanged for more than thirty years. A typical PV cell comprises semiconductor material with at least one p-n junction and front and back side surfaces having current collecting electrodes. When a conventional crystalline PV cell is illuminated, it generates an electric current of about 34 mA/cm² at about 0.6-0.62V. A plurality of PV cells are typically electrically interconnected in series and/or in parallel strings to form a PV module that produces higher voltages and/or currents than a single PV cell.

PV cells may be interconnected in strings by means of metallic tabs, made for example from tinned copper. A typical PV module may comprise 36-100 PV series interconnected cells, for example, and these may be combined into typically 2 to 4 PV strings to achieve higher voltages than would be obtainable with a single PV cell.

In PV modules comprising series-interconnected PV cells, the module only performs optimally when all the series interconnected PV cells are illuminated with approximately similar light intensity. However, if even one PV cell within the series of PV cells is shaded, while all other cells are illuminated, the entire PV module is adversely affected resulting in a substantial decrease in power output from the PV module. It was demonstrated (“Numerical Simulation of Photovoltaic Generators with Shaded Cells”, V. Quaschning and R. Hanitsch, 30^{th} Universities Power Engineering Conference, Greenwich, Sep. 5-7, 1995, p.p. 583-586) that a Photovoltaic module comprising 36 PV cells loses up to 70% of the generated power when only 75% of one PV cell is shaded. In addition to temporary power loss, the module may be permanently damaged as a result of cell shading because when a PV cell is shaded, the cell acts as a large resistor rather than a power generator. In this situation, the other cells in the module drive current through this large resistor which results in heating of the shaded cell which may increase the cell temperature to 160° C. or higher and this can damage the shaded PV cell and the entire PV module if a temperature of this magnitude persists. In order to reduce the risk of PV module damage due to excessive heating in the event of shading, practically all PV modules employ by-pass diodes (BPD) connected across an entire panel or across strings in a panel. Bypass diodes effectively “short out” a single string or an entire module containing shaded cells. Although this approach causes the power generated in the shorted string to be completely lost, it allows the rest of the system to continue producing power and also reduces the heating of the shaded cell.

Since PV modules are generally expected to operate outdoors for typically 25 years without degradation, their construction must withstand various weather and environmental conditions. Typical PV module construction involves the use of a transparent sheet of low iron tempered glass covered with a sheet of polymeric encapsulant material such as ethylene vinyl acetate or thermoplastic material such as urethane on a front side of the module, for example. An array of PV cells is placed onto the polymeric encapsulant material in such a way that the front sides of the cells face the transparent glass sheet. A back side of the array is covered with an additional layer of encapsulant material and a back sheet layer of weather protecting material, such as Tedlar® by DuPont, or a glass sheet. The additional layer of encapsulant material and the back sheet layer typically have openings to provide for electrical conductors connected to PV strings in the module to be passed through the back encupsulant layer and back sheet of weather protecting material to provide for connection to an electrical circuit. For a PV module having an array of two strings of PV cells, typically four conductors are arranged to pass through the openings so that they are all in proximity with each other so they can be terminated in a junction box mounted on the back sheet layer. The glass, encapsulant layers, cells and back sheet layer are typically vacuum laminated to eliminate air bubbles and to protect the PV cells from moisture penetration from the front and back sides and also from the edges. The electrical interconnections of PV strings and connections to bypass diodes are made in the junction box. The junction box is sealed on the back side of the PV module.

In some existing PV modules, an aluminum frame extends around the perimeter of the PV module and protects against damage, provides mechanical strength against wind and snow loads and facilitates mounting of the module to a support. A plurality of supports may be provided to support a plurality of PV modules and such PV modules are typically connected together by cables connected between junction boxes of adjacent modules. Installation of PV modules in this manner can be quite expensive.

The fabrication of the PV modules described above is quite complicated and expensive. Lay up of the PV module before lamination requires a separate step of “bussing” in which the cells are connected in strings by soldering thin busses between them. This increases production costs and limits production capacity.

In addition, locating a junction box on an outer surface of the back sheet of a PV module requires the formation of the above described openings through the back side encapsulant sheet and back side protection sheet which also increases the cost of production and can render the module susceptible to moisture penetration. In addition, the cost of the junction box is significant to the overall cost of PV module. Furthermore, since the junction box typically has a small volume and is made of hermetically sealed plastic, the bypass diodes can become very hot, when a string or module is shaded, which can result in substantial heating inside the junction box and this heat can be transferred to the adjacent PV cells. Therefore there is a risk that the temperature inside the junction box may exceed a safe level resulting in damage to one or more cells in the PV module.

U.S. Pat. No. 6,870,087 B1, 2005, entitled: Assembly Method and Apparatus for Photovoltaic Module, to Patrick Gallagher describes a PV module that comprises only one string of PV cells. Outlet cables are connected to terminal PV cells. These cables are used for electrical connection of one PV module to another in the field. The PV cells string is mounted in a box-like structure comprised of an upper pan and lower pan. The lower pan defines a conduit for the flow of air beneath the PV string. A set of such PV modules is mounted in a sun tracking assembly.

US Patent Publication 2007/0102038 A1, published May 10, 2007 to Kirschning relates to a holding element for photovoltaic modules for fastening a photovoltaic module to a holding device and to a process for the electrical connection of the PV module to the holding element. A conventional junction box is equipped with at least one connecting element provided for inserting onto/into a receiving area of the holding element. This allows direct electric power transfer from the junction box to the holding element, eliminating conventional cables that are normally freely suspended on the back side of PV modules and exposed to wind and weather. The holding element also facilitates the interconnecting neighboring PV modules using receiving elements on the edges of neighboring PV modules thus enabling easy plug- and play interconnection of adjacent PV modules.

### SUMMARY OF THE INVENTION

The present invention may provide for more optimal and less costly PV module fabrication, by eliminating bus bar soldering for interconnection of PV strings within the PV module active area, thereby simplifying and increasing production capacity of PV module lay-up before lamination. The present invention may also eliminate the need for a conventional junction box on the rear surface of the module, thereby decreasing the complexity and cost of PV module production.

The present invention may also simplify PV module interconnection thereby decreasing the cost of PV module installation.

In accordance with one aspect of the invention, there is provided a PV module. The apparatus includes a plurality of PV cells arranged in a planar array having a front side and a back side, the plurality of PV cells being electrically connected together in at least one string having a positive terminal and a negative terminal for supplying electrical energy to a load. The apparatus also includes positive and negative conductors connected to the positive and negative terminals respectively. The apparatus further includes front and back encapsulating sheets disposed on the front and back sides of the array to form a sub-laminate comprised of the array and the front and back encapsulating sheets, the sub-laminate having a first outer perimeter edge. Each of the positive and negative conductors has a respective portion extending from the positive and negative terminals respectively, between the front and back encapsulating sheets and has first and second terminating portions respectively extending outwardly from the first outer perimeter edge of the sub-laminate. The apparatus further includes front and back protectors disposed on the front and back encapsulating sheets respectively to form a laminate comprising the sub-laminate and the front and back protectors. The front and back protectors have second and third outer perimeter edges respectively generally coterminous with the first outer perimeter edge and defining an outer perimeter edge of the laminate. The first and second terminating portions extend outwardly from the outer perimeter edge of the laminate.

The first and second terminating portions may extend from opposite edge portions of the outer perimeter edge of the laminate.

The first and second terminating portions may extend from a common edge portion of the outer perimeter edge of the laminate.

The array may be electrically connected into a plurality of subset strings, each subset string having a positive terminal and a negative terminal and may include conductors disposed entirely between the first and second encapsulating sheets, operably configured to electrically connect the subset strings together, the positive and negative conductors being electrically connected to first and last subset strings of the subset strings that are electrically connected together.

The array may be electrically connected into a plurality of subset strings, each subset string having a positive terminal and a negative terminal and may include conductors disposed outside the outer perimeter edge of the laminate operably configured to electrically connect the subset strings together, the positive and negative conductors being electrically connected to first and last subset strings of the subset strings that are electrically connected together.

The apparatus may further include a frame surrounding the outer perimeter edge of the laminate, the frame having a holder operably configured to hold electrical connectors, the first and second terminating portions of the positive and negative conductors extending into the holder.

The apparatus may further include first and second electrical connectors disposed in the holder, the first and second terminating portions being connected to the first and second electrical connectors respectively.

The apparatus may further include third and fourth electrical connectors in the holder such that the third and fourth electrical connectors are accessible externally of the holder, the third and fourth electrical connectors being electrically connected to the first and second connectors respectively, to enable the array to be connected to a load.

The frame may include a plurality of frame members connected together, wherein each frame member holds a respective portion of the outer perimeter edge of the laminate.

The frame members may have end portions having integral openings therein and may include corner connectors operably configured to be received in the integral openings to connect adjacent frame members together.

At least one of the frame members may have a holder for holding a plurality of electrical connectors.

The array may be electrically connected into a plurality of subset strings, each subset string having a positive terminal and a negative terminal and respective conductors extending from the positive and negative terminals the respective conductors each having a terminating portion extending outwardly of the outer perimeter of the laminate and extending into the holder.

The apparatus may further include a plurality of electrical connectors in the holder, the terminating portions of the conductors being connected to respective electrical connectors in the holder.

The apparatus may further include a bypass diode in the holder and electrically connected to a pair of electrical connectors associated with a subset string of PV cells, to protect the subset string of PV cells from excessive electrical current when the subset string is not producing electric current.

The apparatus may further include a protector operably configured to protect the electrical connectors from weather.

The apparatus may further include a frame member having a receptacle and a first opening adjacent the receptacle and in communication with the receptacle, at least a portion of the outer perimeter edge of the laminate being in the receptacle and whereby at least one of the first and second terminating portions extends across a portion of the outer perimeter edge of the laminate and across a portion of a back side of the laminate in the receptacle and extends through the first opening to facilitate connection of the at least one of the first and second terminating portions to an electrical connector adjacent the back side of the laminate and adjacent the outer perimeter edge of the laminate.

The frame member may have a mounting portion, adjacent the receptacle, for mounting an electrical connector holder to the frame member, the mounting portion being disposed generally parallel to the laminate such that when the electrical connector holder is mounted to the mounting portion, the electrical connector holder extends generally outwardly away from the back side of the laminate.

The first opening may be in the mounting portion.

The apparatus may further include an electrical connector holder on the mounting portion, for holding at least one electrical connector, the electrical connector holder being positioned on the mounting portion such that the at least one of the first and second terminating portions can extend through the first opening into the electrical connector holder and into the electrical connector held therein.

The electrical connector holder may be integral with the electrical connector mount.

The mounting portion may have a plurality of openings for receiving corresponding terminating portions.

The apparatus may further include an electrical connector holder including a plurality of walls defining a plurality of compartments, the plurality of walls including a bottom wall, the bottom wall having pairs of openings in each compartment, each pair of openings being disposed about a respective pair of openings of the plurality of openings in the mounting portion, and each compartment comprising a pair of electrical connectors, whereby positive and negative terminating portions of respective strings of PV cells in the laminate extend through respective openings in the mounting portion and through the pair of openings associated with a respective compartment and wherein the first and second terminating portions may be connected to the respective pair of electrical connectors in the compartment associated with the openings through which the first and second terminating portions extend.

The apparatus may further include bypass diodes connected between respective connectors of the pairs of the electrical connectors associated with respective compartments.

At least some of the walls may have passageways between adjacent compartments.

The passageways may have wires extending therethrough for connecting the electrical connectors of adjacent compartments.

The wires may connect the electrical connectors of adjacent compartments such that the strings of PV cells are electrically connected in a series string having positive and negative terminals and the apparatus may further include first and second pairs of externally accessible electrical connectors, each pair being on an opposite side of the electrical connector holder and adjacent a respective side of the laminate, one connector of each pair being electrically connected together, and one connector of each pair being connected to a respective one of the positive and negative terminals of the series string of PV cells.

The first and second pairs of externally accessible connectors may have coplanar connection axes that extend generally in a plane parallel to a plane of the laminate.

The mounting portion may have a plurality of openings therein for receiving respective terminating portions of respective strings of PV cells within the laminate therethrough.

The apparatus may further include a plurality of electrical connector holders on the mounting portion, each electrical connector holder having a respective pair of electrical connectors and each electrical connector holder being located over a respective pair of openings in the mounting portion to enable the respective terminating portions of respective strings of PV cells to extend through respective openings of the pairs of openings, into respective electrical connector holders for connection to the electrical connectors therein.

The electrical connector holders may have end walls with end openings therein and conduits may extend between end openings of adjacent electrical connector holders.

The apparatus may further include wires extending through the conduits to electrically connect the electrical connectors in adjacent electrical connector holders.

The wires may connect the electrical connectors of adjacent electrical connector holders such that the strings of PV cells are electrically connected in a series string having positive and negative terminals and the apparatus may further include first and second pairs of externally accessible electrical connectors, each pair being on respective electrical connector holders on opposite sides of the laminate, one connector of each pair being electrically connected together, and one connector of each pair being connected to a respective one of the positive and negative terminals of the series string of PV cells.

The first and second pairs of externally accessible connectors may have coplanar connection axes that extend generally in a plane parallel to a plane of the laminate.

In accordance with another aspect of the invention, there is provided a frame apparatus for a PV module. The apparatus includes an elongate body having first and second opposite ends and a module holder between the first and second opposite ends, the module holder being operably configured to hold an edge portion of an outer perimeter edge of the PV module. The apparatus also includes first and second frame connectors disposed at the first and second ends respectively, the first and second frame connectors being operably configured to receive and hold a frame connector element operably configured to connect two adjacent frame members together. The apparatus further includes an electrical connector holder adjacent the module holder, operably configured to hold at least one electrical connector. The apparatus also includes an opening extending between the module holder and the electrical connector holder, the opening being operably configured to receive therethrough at least one conductor extending from the outer perimeter edge of the PV module such that at least one conductor can extend from the outer perimeter edge of the PV module into the module holder and from the module holder into an electrical connector in the electrical connector holder, in a continuous curve.

The elongate body may include first and second parallel spaced apart walls forming the module holder and third and fourth parallel spaced apart walls forming the electrical connector holder, the first and second parallel spaced apart walls extending in a direction opposite to the third and fourth parallel spaced apart walls.

The body may comprise an inner wall between the first and second parallel spaced apart walls and the third and fourth spaced apart walls, the first and second parallel spaced apart walls and the third wall defining an edge space in which a portion of the outer perimeter edge portion of the PV module can be received and the third and fourth parallel spaced apart walls and the inner wall defining an electrical connector space in which at least one electrical connector may be mounted, the opening being disposed in the inner wall.

The apparatus may further include first and second transverse walls extending between the third and fourth walls, the third and fourth parallel spaced apart walls further defining the electrical connector space.

The apparatus may further include first and second connector mounts on the first and second transverse walls respectively operably configured to mount first and second electrical connectors to the first and second transverse walls respectively.

The apparatus may further include a removable cover operably configured to cooperate with the third and fourth walls and the first and second transverse walls to enclose the electrical connector space.

In accordance with another aspect of the invention, there is provided a frame apparatus for a PV module including a laminate having an outer perimeter edge and at least first and second terminating conductors extending from the outer perimeter edge. The apparatus includes a frame member having a receptacle and a first opening adjacent the receptacle and in communication with the receptacle. At least a portion of the outer perimeter edge of the laminate is in the receptacle and at least one of the first and second terminating conductors extends across a portion of the outer perimeter edge of the laminate and across a portion of a back side of the laminate, in the receptacle. The apparatus further includes at least one of the first and second terminating portions extending through the first opening to facilitate connection of at least one of the first and second terminating conductors to an electrical connector adjacent the back side of the laminate and adjacent the outer perimeter edge of the laminate.

The frame member may have a mounting portion, adjacent the receptacle, for mounting an electrical connector holder to the frame member, the mounting portion being disposed generally parallel to the laminate such that when the electrical connector holder is mounted to the mounting portion, the electrical connector holder extends generally outwardly away from the back side of the laminate.

The first opening may be in the mounting portion.

The apparatus may further include an electrical connector holder on the mounting portion, for holding at least one electrical connector, the electrical connector holder being positioned on the mounting portion such that at least one of the first and second terminating conductors can extend through the first opening into the electrical connector holder and into the electrical connector held therein.

The electrical connector holder may be integral with the electrical connector mount.

The mounting portion may have a plurality of openings for receiving respective terminating conductors.

The apparatus may further include an electrical connector holder including a plurality of walls defining a plurality of compartments, the plurality of walls including a bottom wall, the bottom wall having pairs of openings in each compartment, each pair of openings being disposed about a respective pair of openings of the plurality of openings in the mounting portion, and each compartment comprising a pair of electrical connectors, whereby positive and negative terminating conductor of respective strings of PV cells in the laminate extend through respective openings in the mounting portion and into a respective compartment and wherein the first and second terminating conductors are connected to the respective pair of electrical connectors in the compartment associated with the openings through which the first and second terminating portions extend.

The apparatus may further include bypass diodes connected between respective connectors of the pairs of the electrical connectors associated with respective the compartments.

At least some of the walls may have passageways between adjacent compartments.

The passageways may have wires extending therethrough for connecting the electrical connectors of adjacent compartments.

The wires may connect the electrical connectors of adjacent compartments such that the strings of PV cells are electrically connected in a series string having positive and negative terminals and the apparatus may further include first and second pairs of externally accessible electrical connectors, each pair being on an opposite side of the electrical connector holder and adjacent a respective edge of the laminate, one connector of each pair being electrically connected together, and one connector of each pair being connected to a respective one of the positive and negative terminating conductors of the series string of PV cells.

The first and second pairs of externally accessible connectors may have coplanar connection axes that extend generally in a plane parallel to a plane of the laminate.

The mounting portion may have a plurality of openings therein for receiving respective terminating portions of respective strings of PV cells within the laminate therethrough.

The apparatus may further include a plurality of electrical connector holders on the mounting portion, each electrical connector holder having a respective pair of electrical connectors and each electrical connector holder being located over a respective pair of openings in the mounting portion to enable the respective terminating conductors portions of respective strings of PV cells to extend through respective openings of the pairs of openings, into respective electrical connector holders for connection to the electrical connectors therein.

The electrical connector holders may have end walls with end openings therein and conduits may extend between end openings of adjacent electrical connector holders.

The apparatus may further include wires extending through the conduits to electrically connect the electrical connectors in adjacent electrical connector holders.

The wires may connect the electrical connectors of adjacent electrical connector holders such that the strings of PV cells are electrically connected in a series string having positive and negative terminating conductors and the apparatus may further include first and second pairs of externally accessible electrical connectors, each pair being on respective electrical connector holders on opposite edges of the laminate, one connector of each pair being electrically connected together, and one connector of each pair being connected to a respective one of the positive and negative terminating conductors of the series string of PV cells.

The first and second pairs of externally accessible connectors may have coplanar connection axes that extend generally in a plane parallel to a plane of the laminate.

In accordance with another aspect of the invention, there is provided a frame system for a PV module. The system includes a plurality of frame members, operably configured to surround and hold an outer perimeter edge of the PV module. Each frame member includes an elongate body having first and second opposite ends and a module holder between the first and second opposite ends, the module holder being operably configured to hold a respective edge portion of the outer perimeter edge of the PV module. Each frame member also includes first and second frame connectors disposed at the first and second ends respectively, the first and second frame connectors being operably configured to receive and hold a frame connector element operably configured to connect two adjacent frame members together. At least one of the plurality of frame members includes an electrical connector holder adjacent the module holder, operably configured to hold at least one electrical connector, and an opening extending between the module holder and the electrical connector holder, the opening being operably configured to receive therethrough at least one conductor extending from the outer perimeter edge of the PV module such that at least one conductor can extend from the outer perimeter edge of the PV module into the module holder and from the module holder into an electrical connector in the electrical connector holder, in a continuous curve.

In accordance with another aspect of the invention, there is provided a method for making a PV module. The method involves arranging a plurality of PV cells in a planar array, the planar array having a front side and a back side. The method also involves electrically connecting the plurality of PV cells together in at least one string having a positive terminal and a negative terminal. The method further involves connecting positive and negative conductors to the positive and negative terminals respectively. The method also involves affixing front and back encapsulating sheets on the front and back sides respectively of the array, to form a sub-laminate comprised of the planar array and the front and back encapsulating sheets, the sub-laminate having a first outer perimeter edge, the front and back encapsulating sheets being affixed such that each of the positive and negative conductors has a respective portion extending from the positive and negative terminals respectively, between the front and back encapsulating sheets and such that first and second terminating portions of the positive and negative conductors respectively extend outwardly from the first outer perimeter edge of the sub-laminate to facilitate connection to the positive and negative conductors to an external circuit. The method further involves affixing front and back protectors on opposite sides of the sub-laminate to form a laminate comprising the sub-laminate and the front and back protectors, the front and back protectors having second and third outer perimeter edges respectively generally coterminous with the first outer perimeter edge and defining an outer perimeter edge of the laminate, the first and second terminating portions extending outwardly from the outer perimeter edge of the laminate.

The method may involve causing the first and second terminating portions to extend from opposite edge portions of the outer perimeter edge of the laminate.

The method may involve causing the first and second terminating portions to extend from a common edge portion of the outer perimeter edge of the laminate.

The method may involve electrically connecting subsets of the array of PV cells into separate subset strings, each subset string having a positive terminal and a negative terminal and causing the subset strings to be electrically connected together by respective conductors disposed entirely between the first and second encapsulating sheets, the positive and negative conductors being electrically connected to first and last subset strings of the subset strings that are electrically connected together.

The method may involve electrically connecting subsets of the array of PV cells into separate subset strings, each subset string having a positive terminal and a negative terminal and causing the subset strings to be electrically connected together by respective conductors disposed outside the outer perimeter edge of the laminate, the positive and negative conductors being electrically connected to first and last subset strings of the subset strings that are electrically connected together.

The method may involve surrounding the outer perimeter edge of the laminate with a frame having an integral holder operably configured to hold first and second electrical connectors.

The method may involve causing the first and second terminating portions of the positive and negative conductors to extend into the holder, and connecting the first and second terminating portions to the first and second electrical connectors respectively.

The method may involve connecting the first and second electrical connectors to third and fourth electrical connectors on the holder, the third and fourth electrical connectors having portions externally of the holder to enable the array to be electrically connected to a load.

Surrounding the laminate with a frame may involve connecting a plurality of frame members together such that each of the frame members holds a respective portion of the outer perimeter edge of the laminate.

Connecting the plurality of frame members together may involve corner connectors with openings integrally formed in respective frame members.

The method may involve electrically connecting subsets of the array of PV cells into separate subset strings, each subset string having a positive terminal and a negative terminal.

The method may involve connecting each positive and negative terminal of each string to a respective conductor having a respective terminating portion extending into the holder.

The method may involve connecting respective terminating portions of the conductors to a respective electrical connector disposed in the holder.

The method may involve installing a bypass diode in the holder and electrically connecting the bypass diode to a pair of electrical connectors associated with a subset string of PV cells to protect the subset string of PV cells from excessive electrical current when the subset string is not generating electric current.

The method may involve protecting the electrical connectors in the holder from weather.

The method may involve bending at least one of the first and second terminating portions to extend across a portion of the outer perimeter edge of the laminate and across a portion of a back side of the laminate.

The method may involve receiving a portion of the outer perimeter edge of the laminate in a receptacle of a frame member having a first electrical connector such that the at least one of the first and second terminating portions extends through an opening in the frame member to facilitate connection of the at least one of the first and second terminating portions to the first electrical connector when the outer perimeter edge of the laminate is fully received in the receptacle.

The method may involve connecting at least one of the first and second terminating portions to the electrical connector.

The method may involve holding the first electrical connector in a holder on the frame member.

Holding the first electrical connector may involve holding the first electrical connector in a holder disposed on the frame member to extend away from the back side of the laminate when the outer perimeter edge of the laminate is received in the receptacle.

The method may involve connecting the first electrical connector to a second electrical connector having at least a portion extending out of the holder to facilitate connection of the second electrical connector to a load.

In accordance with another aspect of the invention, there is provided a method of framing a PV module. The method involves surrounding and holding an outer perimeter edge of the PV module with a plurality of frame members. The method also involves surrounding connecting frame members together by receiving portions of frame connector elements in respective frame connectors of adjacent frame members. The method further involves holding causing module holders extending between first and second opposite end portions of respective frame members to hold respective edge portions of the outer perimeter edge of the PV module. The method also involves causing at least one conductor extending from an outer perimeter edge of the PV module to extend into the module holder of one of the plurality of frame members and into an electrical connector disposed in an electrical connector holder on an outer portion of the one of the plurality of frame members.

Causing the conductor to extend into the module holder may involve causing at least one conductor to extend in a continuous curve from the outer edge of the PV module to the electrical connector.

The method may involve connecting the electrical connector to an externally accessible terminal mounted on one of the plurality of frame members to enable the PV module to be connected to a load.

The method may involve covering the electrical connector holder to protect the electrical connectors from weather.

Causing the conductor to extend into the module holder may involve causing a plurality of conductors extending from an outer perimeter edge of the PV module to extend into the module holder of one of the plurality of frame members and into respective electrical connectors disposed in an electrical connector holder on an outer portion of one of the plurality of frame members.

The method may involve connecting the respective electrical connectors to respective externally accessible terminals mounted on one of the plurality of frame members to enable the PV module to be connected to a load.

The method may involve installing a bypass diode in the electrical connector holder and connecting the bypass diode to two adjacent electrical connectors to provide for current bypassing of a string of PV cells in the PV module.

The method may involve covering the electrical connector holder to protect the electrical connectors and the bypass diode from weather.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention,

FIG. 1 is an isometric view of a laminated PV module comprising a plurality of PV cells in accordance with a first embodiment of the invention;

FIG. 2A is an isometric view of first and second PV cells interconnected by electrodes and illustrates a positive terminal of the PV module;

FIG. 2B is an isometric view of third and fourth PV cells interconnected by electrodes and illustrates a negative terminal of the PV module;

FIG. 3A is a cross-sectional view of the first and second PV cells, interconnecting electrodes and the positive terminal shown in FIG. 2A, within the PV module;

FIG. 3B is a cross-sectional view of the third and fourth PV cells, interconnecting electrodes and the negative terminal shown in FIG. 2B within the PV module;

FIG. 4 is an isometric view of a PV module comprising an alternate way of connecting end PV cells of adjacent strings of PV cells, according to a second embodiment of the invention;

FIG. 5 is an isometric view of a PV module having terminating portions of respective strings of PV cells extending from opposite edge portions of an outer perimeter edge of the PV module, according to a third embodiment of the invention;

FIG. 6 is an isometric view of a PV module comprising an alternate way of connecting the end PV cells of adjacent strings of PV cells shown in FIG. 5, according to a fourth embodiment of the invention;

FIG. 7 is an isometric view of the PV module shown in FIG. 1 connected to a frame that facilitates termination of electrical conductors of the PV cells in the module, at an outer perimeter edge of the PV module;

FIG. 8 is a fragmented cross-sectional view of a frame member that facilitates holding electrical connectors adjacent the outer perimeter edge of the PV module;

FIG. 9 is an isometric view of a corner connector for connecting adjacent frame members together;

FIG. 10 is an isometric view of a PV module incorporating a frame having two holders for electrical connectors at opposite ends of the panel, according to another embodiment of the invention;

FIG. 11 is an end view of a PV module according to another embodiment of the invention showing externally accessible electrical connectors on opposite side edges of the PV module;

FIG. 12 is an end view of a PV module according to another embodiment of the invention showing externally accessible electrical connectors on opposite sides of the PV module, the electrical connectors having connection axes lying in a plane parallel to the plane of the PV module;

FIG. 13 is an end view of a PV module according to another embodiment of the invention, wherein the PV module has a plurality of strings of PV cells, each string having terminating conductors accessible at the same end of the module and externally accessible connectors at opposite side edges of the module;

FIG. 14 is an end view of a PV module according to another embodiment of the invention, wherein the PV module has a plurality of strings of PV cells, each string having terminating conductors accessible at the same end of the module and externally accessible connectors at opposite sides of the module, the electrical connectors having connection axes lying in a plane parallel to the plane of the PV module;

FIG. 15 is an isometric view of PV modules such as shown in FIG. 11 or 13 having co-operating mating pairs of connectors and alignment pins and openings facilitating direct side-by-side connection of adjacent PV modules without the use of jumper wires between adjacent PV modules;

FIG. 16 is a schematic diagram showing a series connection of a plurality of PV modules of the type shown in FIG. 15;

FIG. 17 is a schematic diagram showing a series connection of a plurality of PV modules shown connected together by a plurality of pairs of jumper wires;

FIG. 18 is a fragmented cross-sectional view of a frame member having a electrical connector holder that extends away from the back surface of the PV module;

FIG. 19 is an exploded view of a frame member and electrical connector holder for use in a PV module having a plurality of strings of PV cells;

FIG. 20 is a perspective view of the apparatus shown in FIG. 19;

FIG. 21 is a rear view of first and second PV modules employing the electrical connector holder shown in FIGS. 19 and 20, connected together by jumper wires;

FIG. 22 is a fragmented perspective view of a frame member similar to that shown in FIG. 19 but with a plurality of separate electrical connector holders mounted thereon.

### DETAILED DESCRIPTION

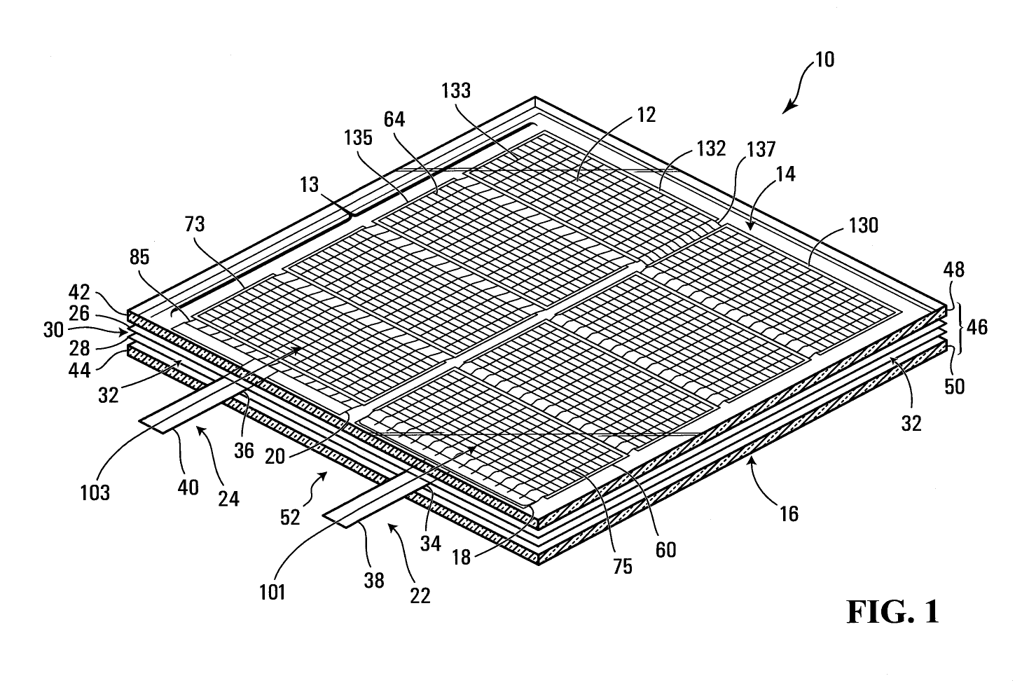

Referring to FIG. 1, a PV module apparatus according to a first embodiment of the invention is shown generally at 10. The apparatus 10 includes a plurality of PV cells shown generally at 12 arranged in a planar array 13 having a front side 14 and a back side 16. The PV cells are electrically connected together to form at least one string. In the embodiment shown the PV cells are connected together to form a string of 8 PV cells, having a positive terminal 18 and a negative terminal 20 for supplying electrical energy to a load. Positive and negative conductors 22 and 24 are connected to the positive and negative terminals 18 and 20 respectively. The apparatus further includes front and back encapsulating sheets 26 and 28 disposed on the front and back sides 14 and 16 respectively of the array 13 to form a sub-laminate 30 comprised of the array and the front and back encapsulating sheets. The sub-laminate 30 has a first outer perimeter edge 32 that extends all the way around the sub-laminate.

Each of the positive and negative conductors 22 and 24 has a respective portion 34 and 36 extending from the positive and negative terminals 18 and 20 respectively, between the front and back encapsulating sheets 26 and 28. The positive and negative conductors 22 and 24 have first and second terminating portions 38 and 40 respectively, that extend outwardly from the first outer perimeter edge 32 of the sub-laminate 30.

Front and back protectors 42 and 44 respectively, are disposed on the front and back encapsulating sheets 26 and 28 to form a laminate 46 comprising the sub-laminate 30 and the front and back protectors. The front and back protectors 42 and 44 have second and third perimeter edges 48 and 50 respectively that extend all the way around the front and back protectors respectively and which are generally co-terminus with the first outer perimeter edge 32 of the sub-laminate. Thus, the first outer perimeter edge 32 of the sub-laminate 30 and the second and third outer perimeter edges 48 and 50 define an outer perimeter edge 52 of the laminate 46. The first and second terminating portions 38 and 40 extend outwardly from the outer perimeter edge 52 of the laminate 46.

In the embodiment shown in FIG. 1, the PV cells 12 are crystalline silicon PV cells having a thickness in a range of between about 0.1 mm and about 0.25 mm and a square area of about 5 cm by about 8 cm. The encapsulating sheets 26 and 28 may be ethylene vinyl acetate or thermoplastic material such as polyvinyl-butyral or polyvinyl-urethane. The front and back protectors 42 and 44 may include respective transparent sheets of low iron tempered glass. The back protector 44 may alternatively include a sheet of electrically insulating, weather protecting material, such as Tedlar® by DuPont. Alternatively, the back protector may be formed of conventional tempered or non-tempered window glass.

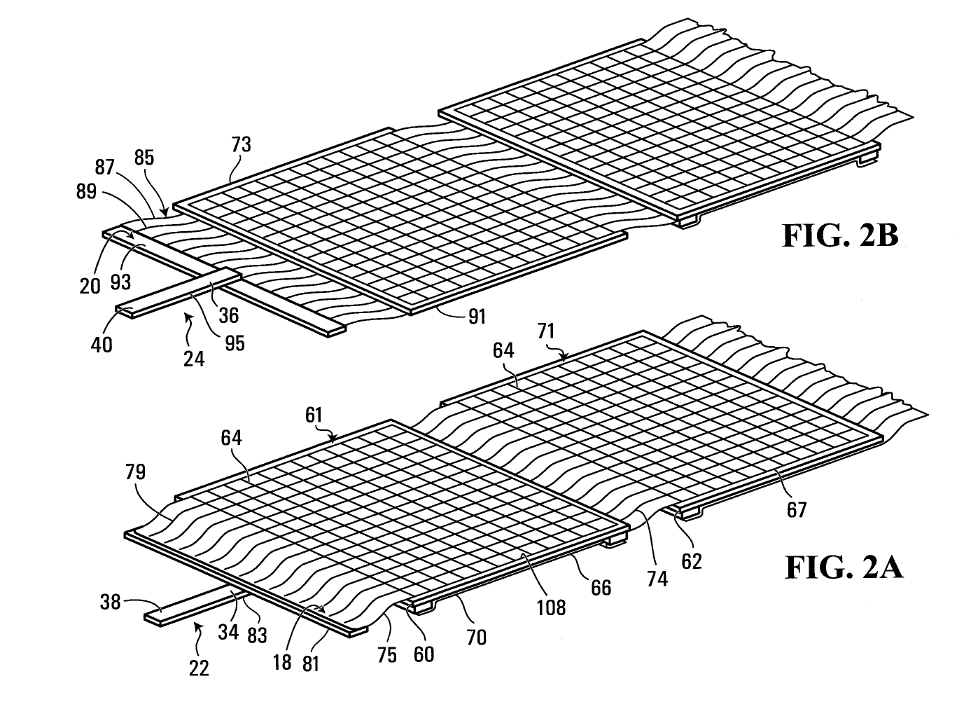

Referring to FIGS. 2A and 2B, the way in which adjacent PV cells are connected and final cells in the string are terminated is shown. In FIG. 2A, first and second PV cells are shown generally at 60 and 62 respectively. The PV cells 60 and 62 are positioned side by side and in this embodiment, have a plurality of screen printed current collecting fingers 64 formed to extend across the front side surfaces 61 and 71 thereof. Back side surfaces (not shown) of the PV cells 60 and 62 are formed to include a back side electrode which may be a planar electrode produced by aluminum or silver-aluminum screen printing on a rear side of the PV cell as is well-known in the art. Thus, the back side surface of each PV cell 60 and 62 is essentially a planar conductor extending generally the full surface of the back side of each PV cell.

The PV cells 60 and 62 are connected together using first and second electrodes, shown generally at 66 and 67 of the type generally described in European Patent No. 1,547,158 to Rubin et al.

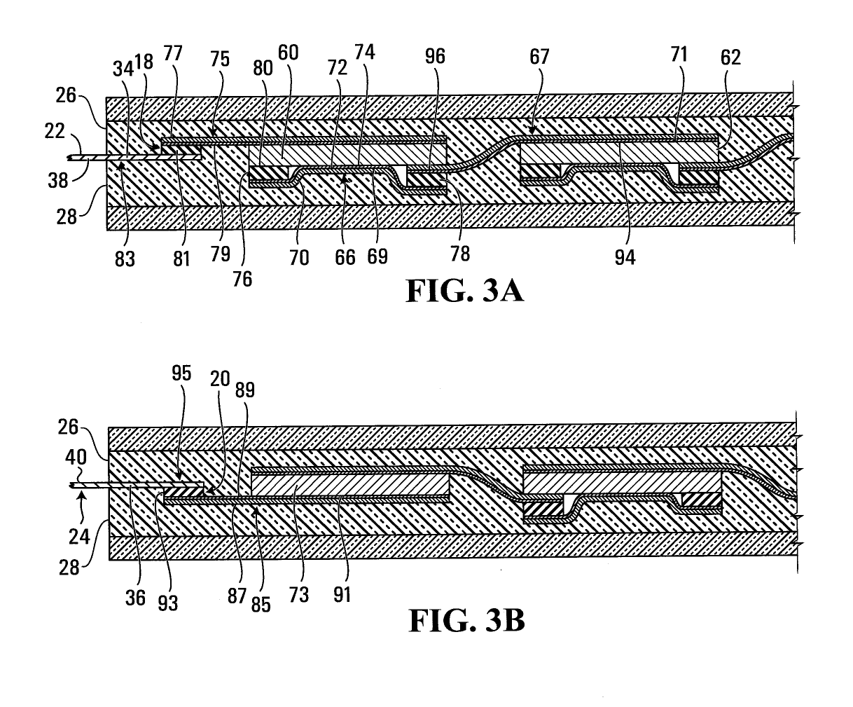

Referring to FIG. 3A, the first electrode 66 includes an electrically insulating optically transparent film 70 having a surface 72 on which a layer of adhesive is provided for securing the film to the back side surface 69 of the PV cell 60. A plurality of substantially parallel electrically conductive wires, only one of which is shown at 74 in FIG. 3A, are embedded into the adhesive layer such that the wires 74 are secured to the film 70 and such that a part of a surface of each of the embedded wires protrudes from the adhesive layer. The part of the surface of each of the embedded wires 74 that protrudes from the adhesive layer is at least partially coated with a coating comprising an alloy having a low melting point to provide for soldering of the embedded wires to the electrically conductive surface of the PV cell 60. The wires 74 are connected together by bus bars 76 and 78 disposed at opposite ends of the electrode. The bus bars 76 and 78 may be formed from respective elongate strips of tinned copper foil to which the ends of the wires 74 are secured by a low melting point alloy such as may be provided by a thin layer of solder. Thus, the bus bar 76 connects all of the first ends of the wires 74 together, and bus bar 78 connects all of the second ends of the wires 74 together. A surface 80 of the bus bar 76 is in direct contact with the back side surface 69 of the first PV cell 60 and the portions of the wire 74 that are covered with the low melting point alloy are connected to the back side surface 69 by heating and pressing the first electrode 66 against the back side surface such that the low melting point alloy melts and solders the wires 74 to the back side surface, while the adhesive secures the film 70 to portions of the back side surface that are not contacted by the coated portions of the wires 74.

The second electrode 67, is similar to the first electrode 66 and is placed on the front side surface 71 of the second PV cell 62 with non-adhesive embedded portions 92 of wires 94 in contact with the front side surface 71. First ends 96 of the wires 94 are connected together by the bus bar 78 that is in electrical contact with the second ends of the wires 74 of the first electrode 66.

In essence, the first electrode 66 faces upwardly and is in electrical contact with the back side surface 69 of the first PV cell 60 and the second electrode 67 faces downwardly and is in electrical contact with the front side surface 71 of the second PV cell. The first and second electrodes 66 and 67 are connected together by the bus bar 78 and thus connect the back side surface 69 of the first PV cell 60 to the front side surface 71 of the second PV cell 62. This method of connecting adjacent PV cells together is repeated for each adjacent pair of PV cells to connect the PV cells together electrically in a series string.

The first PV cell in a string may be considered to be that PV cell that is electrically nearest the positive terminal of the string and the last PV cell in a string may be considered to be that PV cell that is electrically nearest the negative terminal of the string. Therefore, in the embodiment shown in FIGS. 1-3B, PV cell 60 is the first PV cell of the string and PV cell 73 is the last PV cell of the string.

Referring to FIGS. 2A and 3A, the first PV cell 60 is connected to the positive terminal 18 of the string by an electrode 75 similar to the electrode 67 described above. This electrode 75 includes an optically transparent film 77 having wires, one of which is shown at 79 embedded in adhesive on the film such that portions of the wires coated with a low melting point alloy protrude from the adhesive and are secured to the front surface of the first PV cell 60. Common end portions of the wires 79 are electrically connected, such as by soldering, to a bus bar 81, which in this embodiment is a strip of copper foil that acts as the positive terminal 18 for the string. Another strip of copper foil 83 is electrically connected to the bus bar 81 again by soldering, such that the strip of copper foil extends at a right angle to the bus bar and it is this strip of copper foil that acts as the positive conductor 22 having the extending portion 34 between the front and back encapsulating sheets 26 and 28 and the terminating portion 38 that extends outwardly of the outer perimeter edge 52 of the laminate 46.

Referring to FIGS. 2B and 3B, the last PV cell 73 is connected to the negative terminal 20 of the string by an electrode 85 similar to the electrode 66 described above. This electrode 85 includes a film 87 that can be, but need not be, optically transparent, having wires, one of which is shown at 89 embedded in adhesive on the film such that portions of the wires coated with a low melting point alloy protrude from the adhesive and are secured to the back surface 91 of the last PV cell 73. Common end portions of the wires 89 are electrically connected such as by soldering to a bus bar 93, which in this embodiment is a strip of copper foil that acts as the negative terminal 20 for the string. Another strip of copper foil 95 is electrically connected to the bus bar 93 again by soldering, such that the strip of copper foil extends at a right angle to the bus bar 93 and it is this strip of copper foil that acts as the negative conductor 24 having the extending portion 36 between the front and back encapsulating sheets 26 and 28 and the terminating portion 40 that extends outwardly of the outer perimeter edge 52 of the laminate 46.

Referring to FIGS. 3A and 3B, it can be seen that the first and last PV cells 60 and 73 in a string have special “terminating” electrodes 75 and 85 on front and rear surfaces respectively thereof. Otherwise, the electrode arrangements that connect adjacent PV cell together are the same for each remaining PV cell in the string.

Referring back to FIG. 1, the PV cells are arranged in first and second parallel spaced apart rows 101 and 103 with the first and last PV cells 60 and 73 being the first cells in each row. Each row 101 and 103 also has final PV cells, which in this embodiment are labeled 130 and 132 respectively. In order to connect the two adjacently located final PV cells 130 and 132 in each row 101 and 103, the final PV cell 132 in the second row 103 is positioned in the array such that parallel screen printed fingers 133 thereon extend at right angles to the screen printed fingers 64 of the adjacent PV cell 135 in the second row 103 and at right angles to the screen printed fingers 64 of the final PV cell 130 in the first row. This allows an electrode 137 similar to that shown at 67 in FIG. 2A to extend between the final PV cells 130 and 132 in the first and second rows 101 and 103.

Since the back surfaces each of the PV cells in the string is a planar electrode, the orientation of the wires on the electrode that contacts them is irrelevant. Therefore, by placing the final PV cell 132 of the second row such that the screen printed fingers on that cell are at right angles to the screen printed fingers of the final PV cell 130 in the first row, the wires on the electrode extending from the adjacent PV cell 135 can still make contact with the entire back side surface of the final cell 132 in the second row and the wires on the electrode 137 can contact all of the screen printed fingers on the final cell 132 in the second row, and contact the entire back side surface of the final cell 130 in the first row 101.

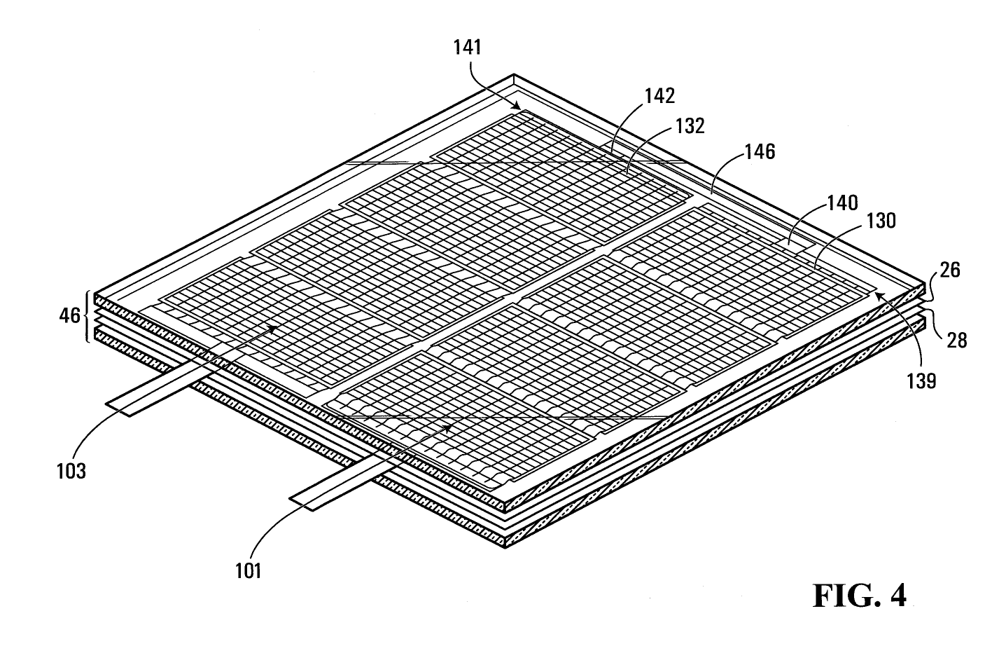

Alternatively, as shown in FIG. 4, electrode 137 of FIG. 1 can be eliminated and replaced with terminating electrodes 139 and 141 of the type shown in FIGS. 3A and 3B on the final PV cells 130 and 132 in each row to form two distinct string portions and these terminating electrodes can be connected together within the laminate to electrically connect the two string portions together. For example, a terminating electrode of the type shown in FIG. 3B can be connected to the back side of the final PV cell 130 of the first row 101 such that an extending portion 140 thereof extends away from the final PV cell and a terminating electrode of the type shown in FIG. 3A can be connected to the front side of the final PV cell in the second row 103. Of course, the final PV cell 132 would not be oriented such that its screen printed fingers are at right angles to the screen printed fingers of the remaining cells, but rather it would be oriented such that its screen printed fingers will extend in the same direction as the screen printed fingers of all of the other PV cells in the array.

With terminating electrodes 139 and 141 connected to the final PV cells 130 and 132 in each row, the terminating portions 140 and 142 extend parallel to each other. In addition, the terminating portion 140 will act as a negative terminal for the first string portion and the terminating portion 142 will act as a positive terminal for the second string portion. Therefore, to electrically connect the first and second string portions together in series, a strip of copper foil such as shown at 146 is connected such as by soldering to the terminating portions 140 and 142. The use of copper foil for the terminating portions 140 and 142 and to connect the terminating portions together keeps the thickness of the materials used in this area to a minimum, lessening the risk of voids in the laminate 46.

The total number of strings is limited by the size of the PV module. Typically the number of strings will not exceed 10. The number of PV cells per string depends on the generated power and as will be appreciated later, the type of bypass diode that should be sufficient to dissipate heat when the PV cell(s) in the string is (are) shaded. Desirably the total number of 6-inch crystalline silicon PV cells in two interconnected series PV strings should not exceed 24.

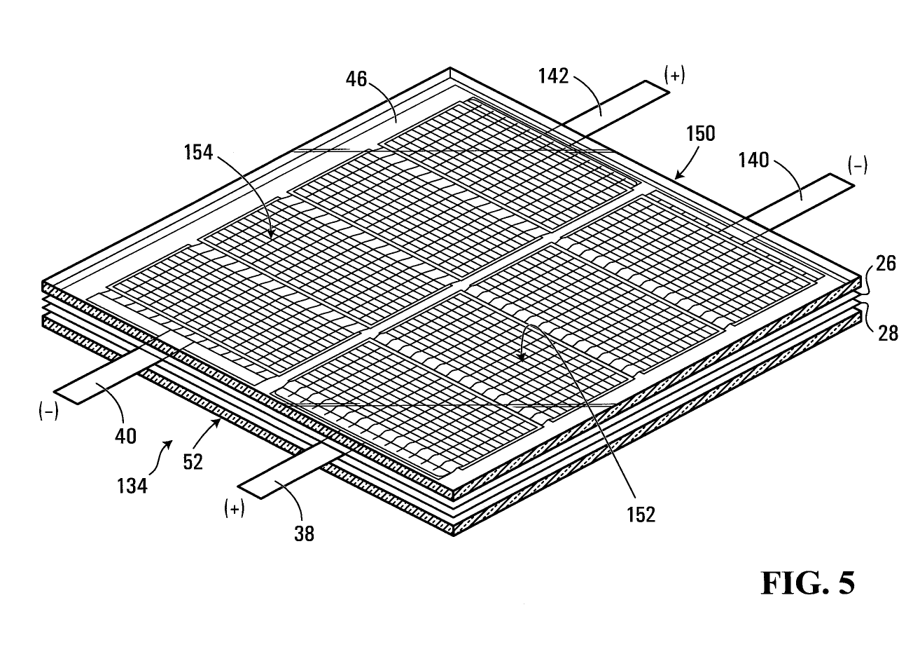

Referring to FIG. 5, the PV module shown in FIG. 4 can be divided into two separately accessible strings of PV modules by extending the terminating portions 140 and 142 out through an end edge portion 150 of the outer perimeter edge 52, opposite the first common edge portion 134 from which the previously mentioned positive and negative terminating portions 38 and 40 extend. Thus, a first string of PV cells is shown generally at 152 and a second string is shown generally at 154. In this embodiment, the terminating portion 38 acts as a positive terminating portion for the first string 152 and the terminating portion 140 acts as the negative terminating portion for the first string. Similarly, the terminating portion 142 acts as the positive terminating portion for the second string 154 while the terminating portion 40 acts as the negative terminating portion for the second string. Again the outer perimeter edge 52 of the laminate is completely sealed and only the terminating portions 38, 40, 140, and 142 extend outwardly therefrom.

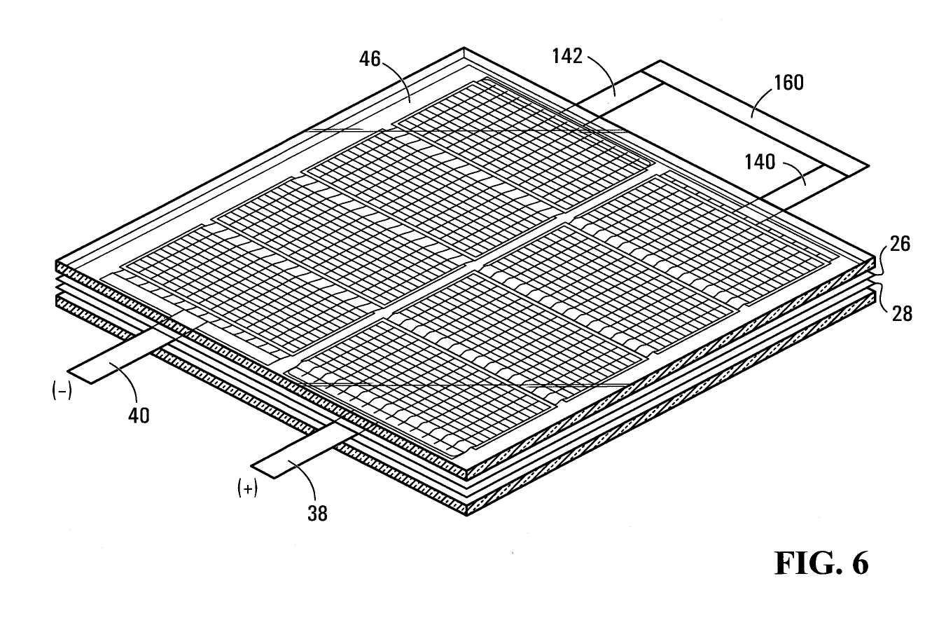

Referring to FIG. 6, the terminating portions 140 and 142 shown in FIG. 5, may be connected externally of the laminate 46 by an external bus bar 160 formed of a thin copper foil, for example, by soldering the external bus bar to the terminating portions 140 and 142. Alternatively, the bus bar 160 could be connected to the terminating portions 38 and 40.

The embodiment of FIG. 6 allows the PV cells to occupy substantially most of the overall PV module area thus improving its efficiency in terms of generated power per occupied area. This design also eliminates one production step namely bus bar soldering inside the PV laminate which can decrease production cost and increase production throughput.

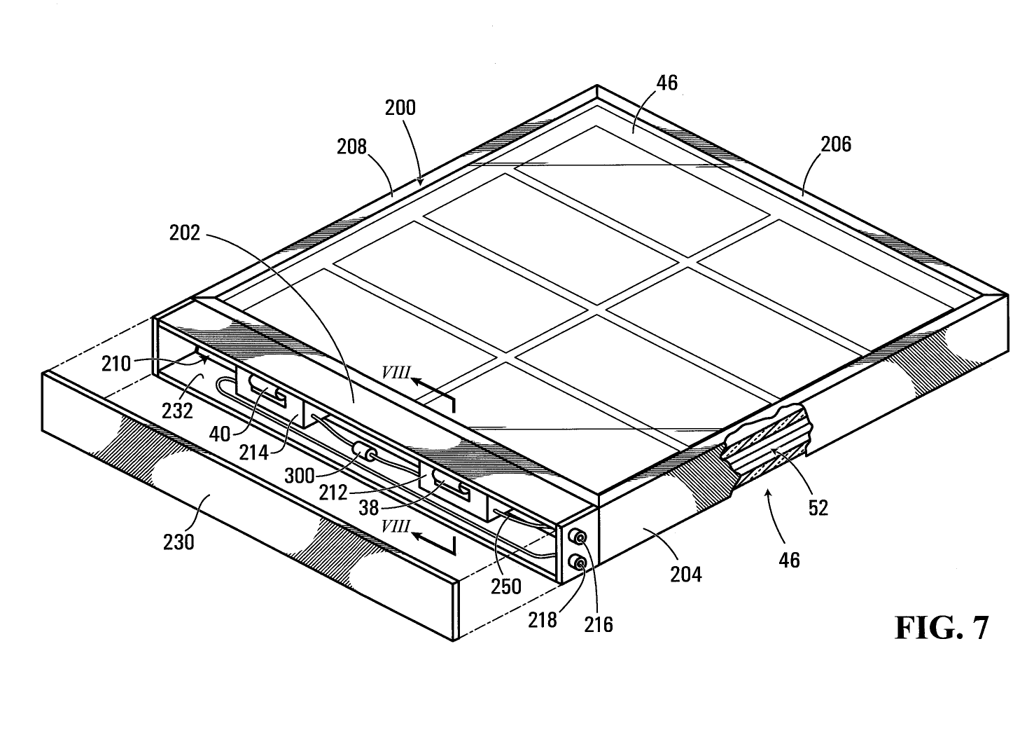

Referring to FIG. 7, the laminate 46 of FIG. 1 is shown surrounded by a frame 200 surrounding the outer perimeter edge 52 of the laminate. In the embodiment shown, the frame comprises a plurality of frame members 202, 204, 206, and 208 that are connected together to surround the entire perimeter of the laminate 46. The first frame member 202 has a holder shown generally at 210, operably configured to hold electrical connectors. In this embodiment the holder 210 holds first and second electrical connectors 212 and 214. The first and second terminating portions 38 and 40 are connected to the first and second electrical connectors 212 and 214 respectively. Third and fourth electrical connectors 216 and 218 are disposed on the holder 210 and are accessible externally of the holder and are connected to the first and second electrical connectors 212 and 214 respectively, to enable the string of PV cells in the laminate 46 to be connected to a load.

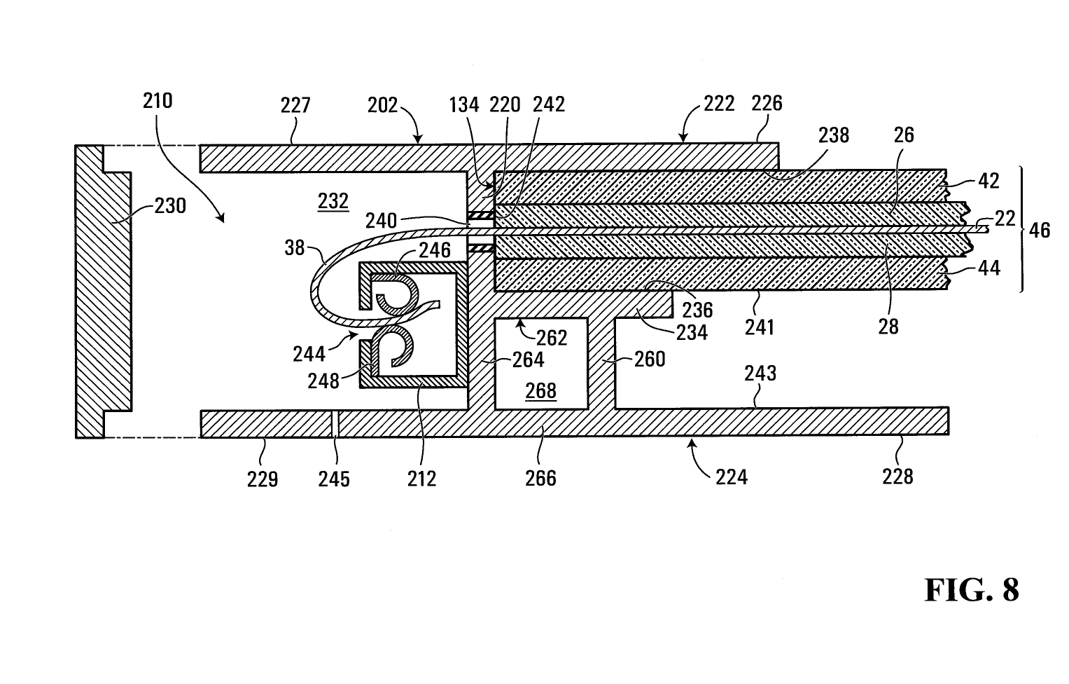

A fragmented cross-sectional view of the first frame member 202 is shown in FIG. 8. In this embodiment, the first frame member 202 includes a main web portion 220 to which is connected first and second parallel spaced apart portions 222 and 224 respectively. Each of the first and second parallel spaced apart portions 222 and 224 have inwardly and outwardly extending portions 226, 227 and 228, 229 respectively. In this embodiment, the inwardly extending portion 228 of the second parallel spaced apart portion 224 is longer than the inwardly extending portion 226 of the first parallel spaced apart portion 222. The outwardly extending portions 227 and 229 have the same length to permit a cover 230 to be connected thereto to protect the electrical connectors in the electrical connector holder from weather.

The web portion 220 and the outwardly extending portions 227 and 229 are arranged to form a longitudinal channel seen best at 232 in FIG. 8 and act as the holder 210 for holding the first and second electrical connectors. A small opening 245 may be provided in the outwardly extending portion 229 to provide for escape of any condensed moisture from the holder 210.

Still referring to FIG. 8, in the embodiment shown, the first frame member 202 also includes a third parallel portion 234 parallel to and, between the inwardly extending portions 226 and 228 of the first and second parallel spaced apart portions 222 and 224. A distance between a first surface 236 of the third parallel portion 234 and a second surface 238 of the first parallel spaced apart portion 222 is about equal to the thickness of the laminate 46 to enable the common edge portion 134 of the outer perimeter edge (52) of the laminate 46 to be received between the surface 236 and the surface 238. Thus, the surfaces 236 and 238 and the web portion 220 define a receptacle for receiving and holding the common edge portion 134 of the outer perimeter edge of the laminate 46. Liquid sealant material, for example, may be applied between the surfaces 238 and 236 and the front and back sides of the laminate 46 to seal the common edge portion 134 in the receptacle.

An opening 240 is provided in the web portion 220 to enable the terminating portion 38 of the positive conductor 22 to be received through the opening 240 when the common edge portion 134 is fully received in the receptacle formed by the surfaces 236 and 238 and the web portion. This enables the terminating portion 38 to extend into the channel 232 formed by the holder 210. A rubber Mylar® or propylene grommet 242, for example, may be installed in the opening 240 to eliminate the possibility that the terminating portion 38 can make electrical contact with the web portion 220, especially where the web portion or the entire first frame member 202 is formed of a metallic material such as an aluminum extrusion. In addition, or alternatively, the terminating portion may be partially covered with an insulating material such as Mylar®, polypropylene or another polymeric material at least at the point it passes through the opening 244, while leaving a suitably sized portion free of insulating material to facilitate connection of the terminating portion to the electrical connector 212. Desirably, the insulating material should be able to withstand a dielectric stress of about 8 kV. Alternatively the frame member 202 may be formed from an insulating material, such as a plastic extrusion, in which case the grommet 242 may not be required for electrical insulation but may be desirable to provide a soft edge on which the terminating portion 38 may rest.

In this embodiment, the first electrical connector 212 is of the type provided by Multi-Contact AG of Basel, Switzerland and includes an opening 244 for receiving the terminating portion 38. Opposing springs 246 and 248 of the electrical connector 212 are disposed inside the opening and are biased towards each other. The terminating portion 38 is pushed into the opening 244 and between the springs 246 and 248 such that the springs grasp opposite sides of the terminating portion and thus secure it mechanically while providing an electrical connection to the terminating portion. A wire shown best at 250 in FIG. 7 is electrically connected to the electrical connector 212 and is further connected to the third electrical connector 216 disposed externally of the holder 210 to provide for electrical connection of the terminating portion 38 to the third electrical connector.

Referring back to FIG. 8, desirably, the electrical connector 212 is positioned inside the channel 232 in a position such that the terminating portion 38 extends in a continuous curve from the common edge portion 134 to the electrical connector 212.

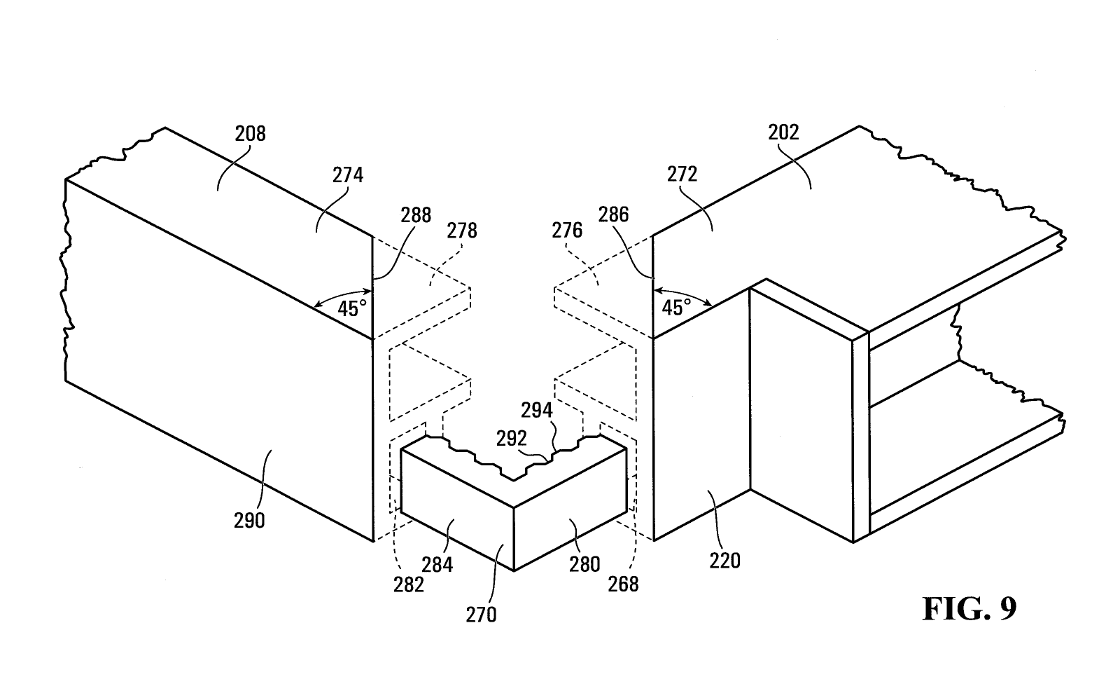

Still referring to FIG. 8, the first frame member 202 further includes a parallel web portion 260 that together with respective portions 262, 264, and 266 co-operate to define an opening 268 operably configured to receive a portion of an interlocking corner connector, as shown at 270 in FIG. 9, to connect adjacent frame members together. For example, referring to FIG. 9, a first end portion 272 of the first frame member 202 is shown and a second end portion 274 of the fourth frame member 208 is shown. Cross-sectional configurations of the first and fourth frame members are extended out using broken lines as shown at 276 and 278 respectively to show how the corner key co-operates with respective openings in the frame members.

The first opening 268 in the first frame member 202 is shown ready to receive a first portion 280 of the corner connector 270. A similar opening 282 of the fourth frame member 208 is shown ready to receive a second portion 284 of the corner connector 270. The first and second portions 280 and 284 of the corner connector 270 are disposed at right angles to each other and the first and fourth frame members have end edges 286 and 288 that are disposed at a 45 degree angle to the longitudinal axes of the first and fourth frame members 202 and 208 such that when the first and second portions 280 and 284 of the corner connector 270 are fully received in the openings 268 and 282 respectively, the end edges 286 and 288 of the corresponding frame members 202 and 208 are in abutment and the frame members are disposed at right angles to each other.

In the embodiment shown, the portions 280 and 284 of the corner connector 270 are formed such that at least one surface thereof has a plurality of grooves, one of which is shown at 292, and ridges, one of which is shown at 294, to facilitate gripping the respective frame member to which the corresponding portion 280 and 284 is associated.

Referring back to FIG. 7, a bypass diode 300 may optionally be connected between the first and second electrical connectors 212 and 214 to provide for shading protection of the PV cells in the array in the event that the array is connected to a system of PV modules and the PV module shown in FIG. 7 becomes shaded. Thus the connector holder 210 also serves as a diode holder to hold a bypass diode for protecting the PV module.

The first frame member 202 described in connection with FIG. 7 would be suitable for use with the laminate 46 shown in FIG. 1 or 4.

The laminates shown in FIGS. 5 and 6 may also be surrounded by frame members using the corner connector 270 for connecting adjacent frame members together.

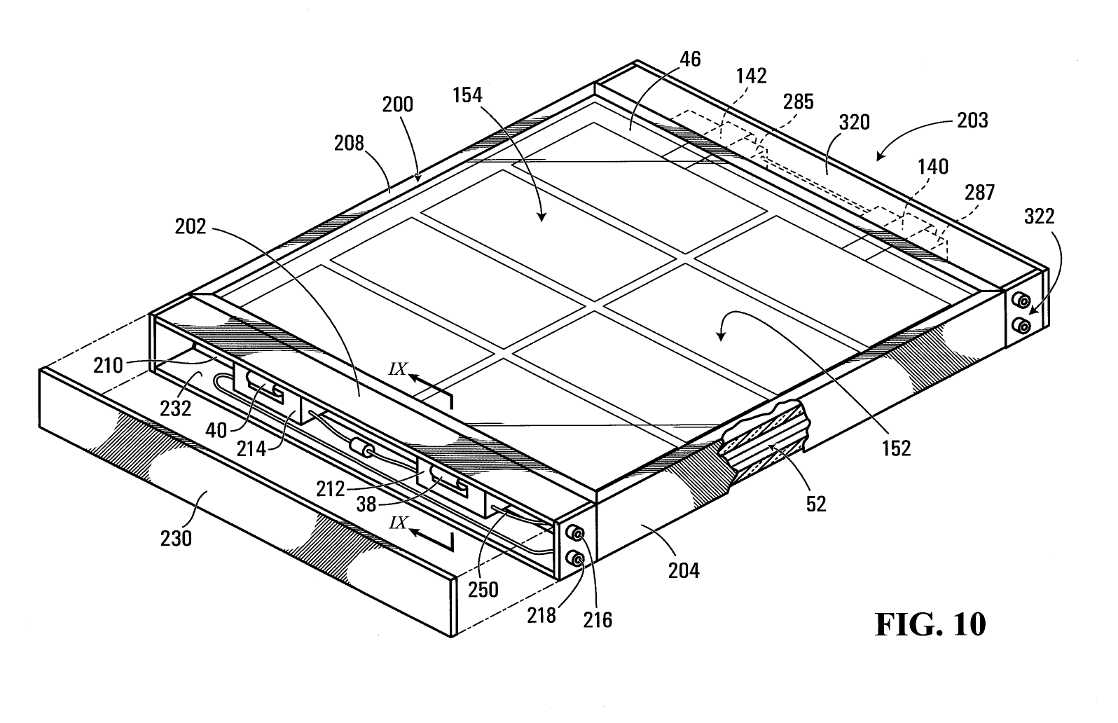

To facilitate use of the frame members with the laminates shown in FIGS. 5 and 6, a frame arrangement similar to that shown in FIG. 7 may be used with the exception that the frame member 206 opposite the frame member 202 in FIG. 7 is replaced with a fifth frame member 203 similar to that of the first frame member 202, as shown in FIG. 10. In this embodiment, the fifth frame member 203 has a connector holder 320 in which electrical connectors 285 and 287 similar to those shown at 212 and 214 in FIG. 10 are located to receive terminating portions 140 and 142 respectively. Thus, in this embodiment there would be first and second strings 152 and 154 of PV cells, each having positive and negative terminating portions (38, 142, and 140, 40) and corresponding electrical connectors 212, 287 and 285, 214 at opposite ends of the PV module. The electrical connectors 287 and 285 may be connected to respective externally accessible electrical connectors, shown generally at 322, to facilitate electrically connecting the individual strings to external loads or to other strings within an adjacent PV module.

If there is no need to connect the individual strings to external loads or other strings outside the PV module, the externally accessible electrical connector 322 can be eliminated and a wire may be connected between the electrical connectors 285 and 287 to connect the first and second strings 152 and 154 together.

If the laminate shown in FIG. 6 were used with the frame configuration shown in FIG. 10, the bus bar 160 may be disposed within the second frame electrical connector holder 320 and there need not be any electrical connectors in the second frame holder. Where the holder 320 is formed of a conductive material, it will be appreciated that the bus bar 160 should be insulated therefrom, such as by covering relevant portions of the terminating portions 140 and 142 and the bus bar 160 with an electrically insulating material such as Mylar, for example.

Referring back to FIG. 7, a particular connector arrangement is shown whereby the first and second electrical connectors 212 and 214 are connected to the positive and negative terminating portions respectively of a single string of PV cells and a bypass diode 300 is connected across the positive and negative terminating portions 38 and 40 to provide shading protection for the overall PV module. The first and second electrical connectors 212 and 214 are electrically connected by wires to third and fourth electrical connectors 216 and 218 which are, in this embodiment, externally accessible from a side edge of the frame member and hence the PV module.

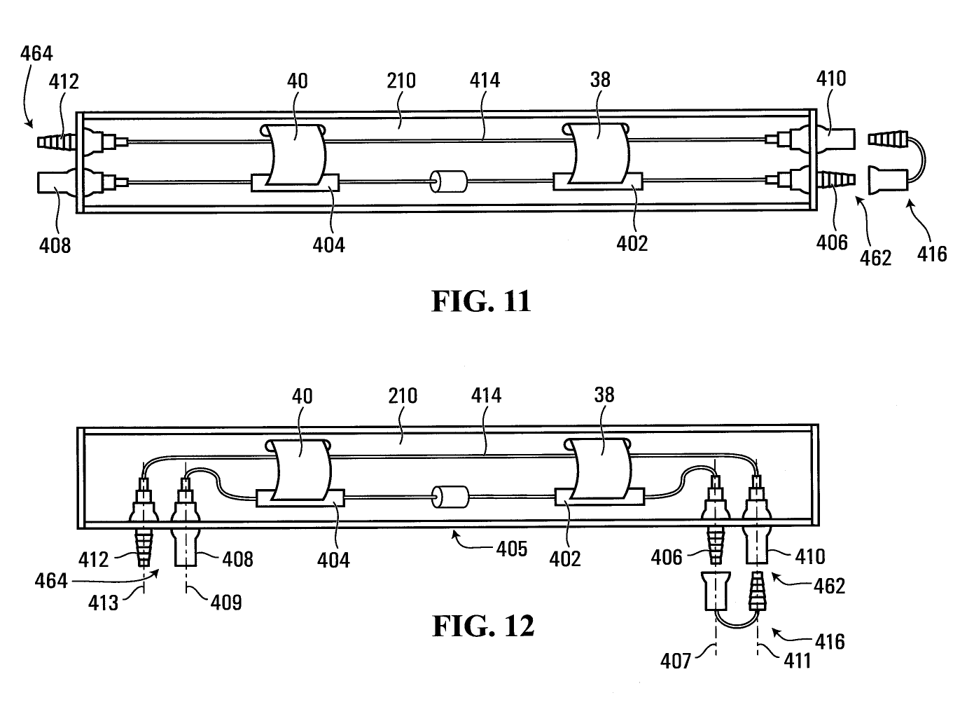

Alternative connector arrangements to those shown in FIG. 7 may be provided, as shown in FIGS. 11 and 12 for example. In FIG. 11, the holder 210 of the first frame member of FIG. 8 is configured to hold first and second connectors 402 and 404. In this embodiment the first and second connectors 402 and 404 are connected to third and fourth externally accessible connectors 406 and 408 respectively. The third and fourth externally accessible connectors 406 and 408 are disposed on opposite sides of the holder 210 and thus are accessible from opposite side edges of the PV module. The apparatus further includes fifth and sixth electrical connectors 410 and 412 disposed adjacent the third and fourth connectors 406 and 408 respectively and thus are also accessible from respective opposite side edges of the PV module.

In this embodiment the fifth and sixth connectors 410 and 412 are connected together by a wire 414. The third and fifth connectors 406 and 410 thus form a first pair 462 of externally accessible connectors at a first side of the PV module and the fourth and sixth connectors 408 and 412 form a second pair 464 of externally accessible connectors at a second, opposite side of the PV module.

A jumper shown generally at 416 may be used at either side of the PV module to jumper the pair 462 or 464 of electrical connectors at that side, if desired. For example, in the embodiment shown, the jumper 416 is used to connect together the first pair 462 so that external electrical access to the module is provided by the second pair 464. Alternatively, external electrical access can be provided by the first pair 462 by simply installing the jumper on the second pair 464.

Referring to FIG. 12, an alternative connector arrangement is shown. In this embodiment, the first and second connectors 402 and 404 and the positive and negative terminating portions 38 and 40 are positioned in the same locations as shown in FIG. 11, however the connectors 406, 408, 410 and 412 are positioned on a back side 405 of the connector holder 210 rather than on side edges of the frame member and PV module, such that connection axes 407, 409, 411, and 413 of the connectors 406, 408, 410, and 412 lie in a common plane parallel to a plane of the PV module.

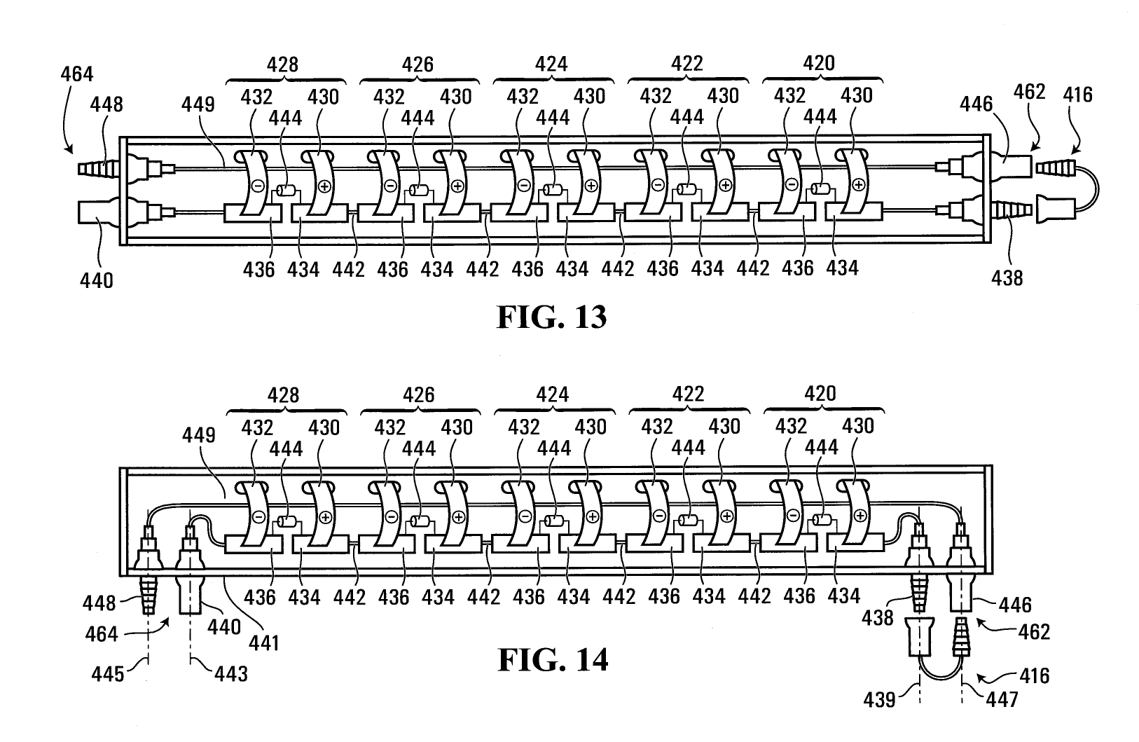

Referring to FIG. 13, the PV module may comprise a plurality of strings of PV cells, each associated with a respective pair 420, 422, 424, 426, and 428 of positive and negative terminating conductors 430 and 432. Each positive and negative terminating conductor 430 and 432 is connected to a respective electrical connector 434 and 436. The electrical connector 434 associated with the positive terminating conductor 430 of the first string is connected to a first externally accessible electrical connector 438 on a first side edge of the frame member. The electrical connector 436 associated with the negative terminating conductor 432 of the final pair 428 is connected to a second externally accessible electrical connector 440 on a second, opposite side edge of the frame member. In between the first and last strings, the remaining strings are connected in series by connecting jumper wires 442 between respective electrical connectors 434, 436 associated with the positive and negative terminating conductors 430 and 432 of adjacent strings. To provide for shading protection of each individual string, bypass diodes shown at 444 are electrically connected between the electrical connectors 434 and 436 associated with a respective string.

In this embodiment, the apparatus further includes third and fourth externally accessible electrical connectors 446 and 448 disposed on opposite sides of the module, adjacent the first and second externally accessible electrical connectors 438 and 440 respectively and connected by a wire 449 to each other. The first and third externally accessible electrical connectors 438 and 446 thus act as a first pair 462 of electrical connectors for the PV module and the second and fourth externally accessible electrical connectors 440 and 448 act as a second pair 464 of electrical connectors for the PV module.

The pairs 462 and 464 of connectors at opposite ends of the PV module permit a jumper such as shown at 416 in FIG. 11 to be used at either end of the PV module to enable the pair of connectors at the opposite end to be used for electrical access to the PV module as described in connection with FIG. 11.

The embodiment shown in FIG. 13 permits a plurality of strings of PV cells to be individually accessible through their respective positive and negative terminating conductors 430 and 432 and individual bypass diodes 444 can be associated with each respective string to thereby protect the strings from damage that may result due to shading.

Referring to FIG. 14, the externally accessible electrical connectors 438, 440, 446 and 448 are disposed on a rear facing edge 441 of the frame member rather then on end edges as shown in FIG. 13. Again the connectors 438, 440, 446, and 448 have connection axes 439, 443, 447 and 445 that lie in a common plane parallel to the plane of the PV module. By placing these connectors 438, 440, 446, and 448 on the rear facing edge, adjacent PV modules may be positioned closer together than they can be using the apparatus shown in FIG. 13. It will be appreciated that on the opposite edge of the PV module, the strings are interconnected in a similar manner, but without bypass diodes.

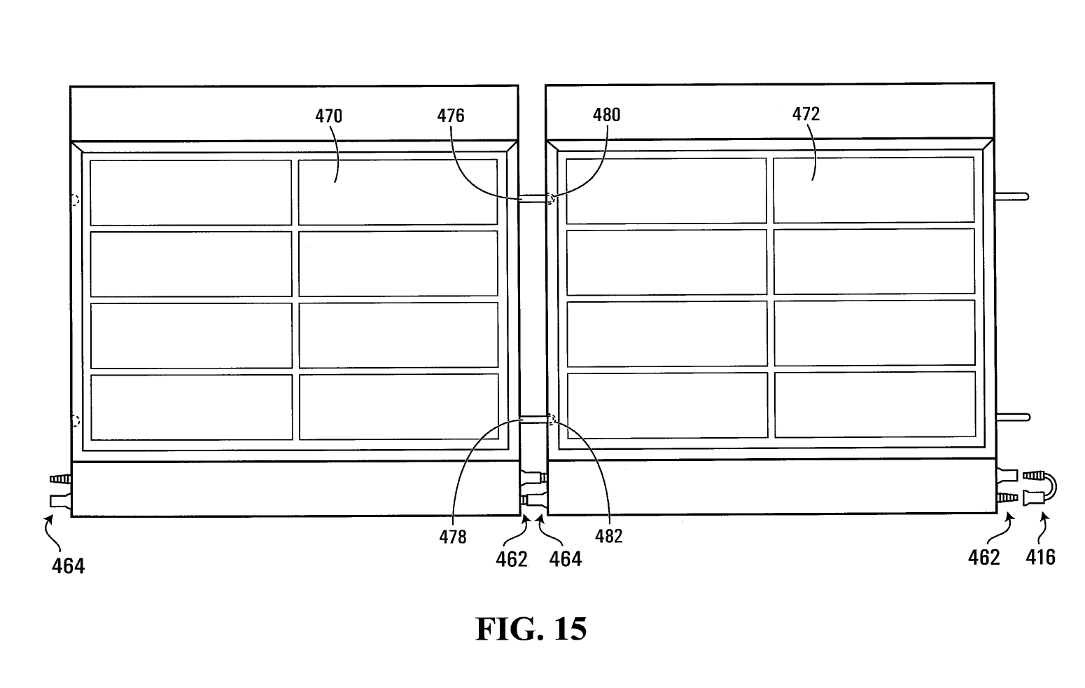

Referring to FIG. 15, a pair of PV modules such as shown at 470 and 472 may be connected together by placing the PV modules side by side as shown such that respective pairs 462 and 464 of connectors on respective PV modules 470 and 472 are aligned with each other and engaged. To facilitate this alignment and engagement, pins such as shown at 476 and 478 on an edge of PV module 470 are received in receptacles 480 and 482 respectively of the adjacent module 472.

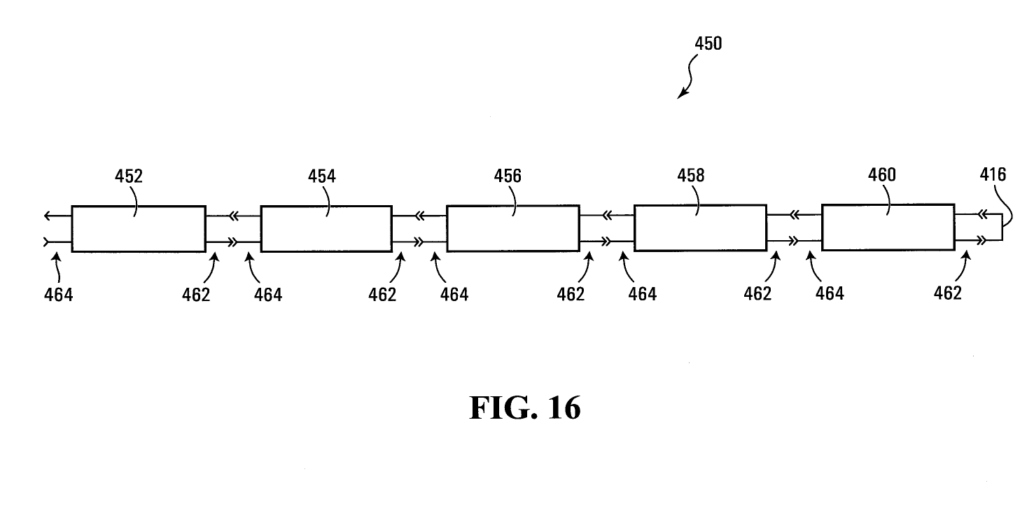

The jumper 416 may be connected to the pair 462 of connectors on the second module 472 thereby enabling electrical access to the positive and negative terminals of the system of PV modules to be provided by the pair 464 of connectors on the first PV module 470. Referring to FIG. 16, it will be appreciated that a plurality of PV modules may be connected together in the way shown in FIG. 15, as shown generally at 450 in FIG. 16. In this embodiment, each PV module 452, 454, 456, 458, and 460 has first and second pairs 462 and 464 of connectors on opposite sides of each PV module. Respective male and female connectors of each pair 462 and 464 are connected to corresponding mating ones of the pair of connectors of the adjacent PV module except for the first and final PV modules 452 and 460 in which the pair of connectors on opposite sides of respective ones of the first and final PV module 452 and 460 are un-terminated. Either of these pairs 462 or 464 may be terminated by a jumper 416 to connect the plurality of PV modules 452 to 460 together, in series. This provides a convenient way of connecting the panels together and facilitates maintenance on the PV modules. The configuration shown in FIG. 16 however does not permit any one of the PV modules in the system, such as PV module 456, to be easily removed because all of the modules on each side or at least one side of the PV module to be removed must be pushed aside to make room to allow the connectors on the PV module being removed to be disengaged. This can be overcome by use of the embodiments shown in FIG. 12, 14, or 17 for example, where jumper wires connect adjacent PV modules together.

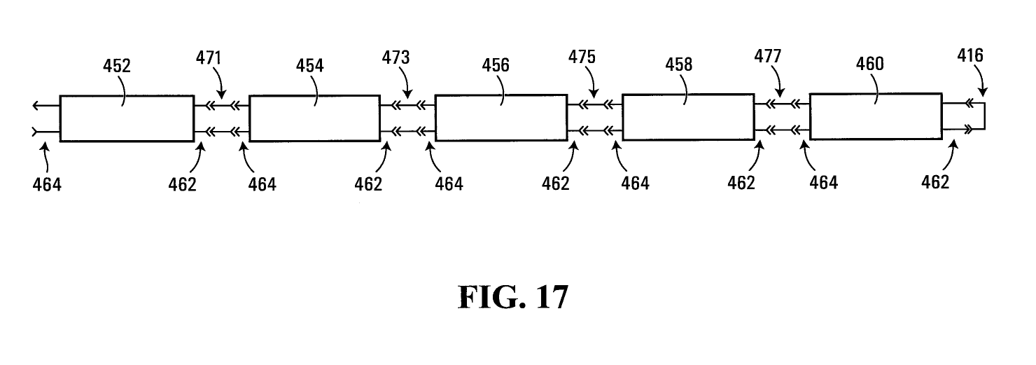

Referring to FIG. 17, the PV modules 452, 454, 456, 458 and 460 shown in FIG. 16 may alternatively be connected together in series using a plurality of pairs 471, 473, 475 and 477 of jumper wires having connectors complementary to corresponding connectors on adjacent PV modules in the series. In this embodiment, the PV modules electrically connected in series need not be physically located adjacent each other and in a common plane as in the embodiment shown in FIG. 15.

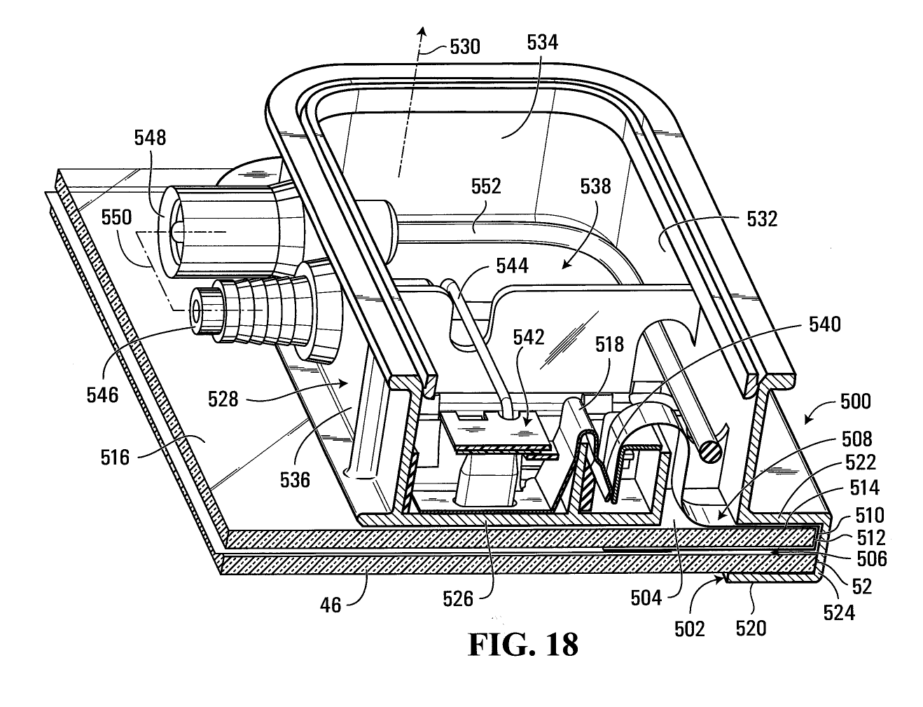

Referring to FIG. 18, a frame member according to an alternate embodiment of the invention is shown generally at 500. This frame member has a receptacle shown generally at 502 and a first opening 504 adjacent the receptacle and in communication with the receptacle. A portion 506 of the outer perimeter edge 52 of the laminate 46 is received in the receptacle 502. At least one of the first and second terminating portions is shown generally at 508 and since the terminating portion extends from the outer perimeter edge 52 of the laminate 46, a portion 510 of the terminating portion extends across a portion 512 of the outer perimeter edge 52 of the laminate 46 and across a portion 514 of the back side 516 of the laminate in the receptacle 502 and extends through the first opening 504 to facilitate connection of the terminating portion 508 to an electrical connector 518 adjacent a back side 516 of the laminate 46 and adjacent the outer perimeter edge 52.

In this embodiment, the receptacle 502 is formed by forming a generally U-shaped channel in the frame member. The U-shaped channel has first and second parallel leg portions 520 and 522 and a connecting portion 524 extending therebetween. The first and second parallel leg portions 520 and 522 are spaced apart about the same thickness as the laminate 46 so that the edge portion of the laminate is snugly received in the receptacle 502.

In this embodiment, the frame member 500 has a mounting portion 526 adjacent the receptacle 502 for mounting an electrical connector holder 528 to the frame member 500. The mounting portion 526 is disposed generally parallel to the laminate 46 such that when the electrical connector holder 528 is mounted to the mounting portion 526, or integrally formed therewith, the electrical connector holder extends generally outwardly, away from the back side 516 of the laminate 46 as indicated by arrow 530. In this embodiment, the electrical connector holder 528 is integral with the frame member 520 and mounting portion 526 and has a plurality of walls, three of which are shown at 532, 534, and 536 that define a cavity 538 in which the electrical connector 518 is held.

It will be appreciated that the electrical connector holder 528 is positioned on the mounting portion 526 such that at least one of the first and second terminating portions (508) can extend through the first opening 504 and into the electrical connector holder and into the electrical connector held therein.

In this embodiment the electrical connector includes a first terminator 540 for receiving the terminating portion 508 therein, and includes a second terminator shown generally at 542 for receiving a wire 544 therein. First and second externally accessible connectors 546 and 548 are mounted to the wall 536 and lie in a plane 550 that is parallel to a plane of the back side surface 516 of the laminate. The wire 544 is connected to the first externally accessible connector 546 and a second wire 552 is connected to the second externally accessible electrical connector.

It will be appreciated that a mirror image of the structure shown in FIG. 18 extends symmetrically opposite the structure shown and thus provides for termination of the second terminating portion in a similar manner and provides for additional connectors similar to connectors 546 and 548 wherein the wire 552 is connected to at least one of the additional connectors and a wire similar to that shown at 544 is connected to the other of the similar connectors to connectors 546 and 548 to provide for connection to the second terminating portion. It will be appreciated that the structure shown in FIG. 18 and the mirror image thereof may be suitable for a PV cell having a single string of PV cells with only first and second terminating portions of the type shown at 508.

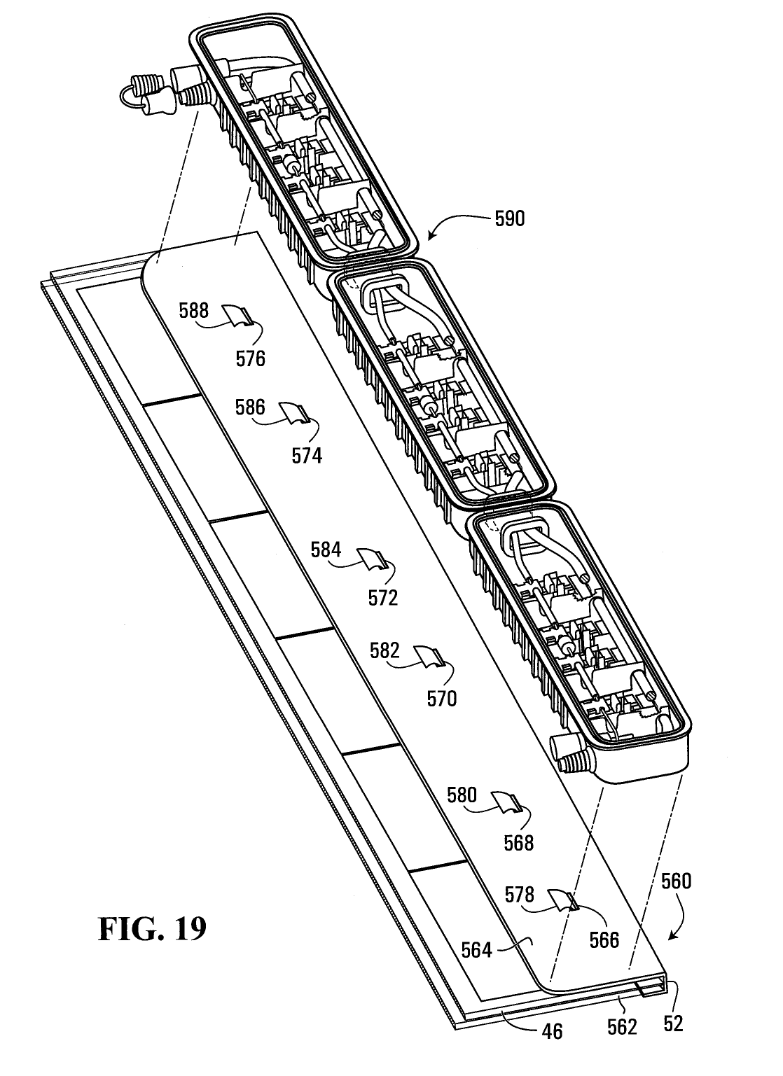

In a case where the PV module has more than one string of PV cells, such as 3 strings, the structure shown in FIG. 18 is replicated and additional openings are provided in the mounting portion, accordingly as shown in FIG. 19.

Referring to FIG. 19, a frame apparatus similar to that shown in FIG. 18 for use with PV modules having a plurality of strings is shown generally at 560 and includes a receptacle 562 and a mounting portion 564 having a plurality of openings 566, 568, 570, 572, 574, and 576 all spaced apart appropriately to receive first and second terminating portions 578, 580, 582, 584, 586, and 588, of respective strings of PV cells in the PV module. As can be seen, the terminating portions 578, 580, 582, 584, 586, and 588 extend through openings 566, 568, 570, 572, 574, and 576 respectively. It will be appreciated that in each case, since the terminating portions 578 emanate from the outer perimeter edge 52 of the laminate 46, each terminating portion follows a path similar to that shown in FIG. 18 where a portion of the terminating portion extends across a portion of the outer perimeter edge of the laminate and across a portion of the back side of the laminate in order to extend through a respective opening 566, 568, 570, 572, 574, and 576.

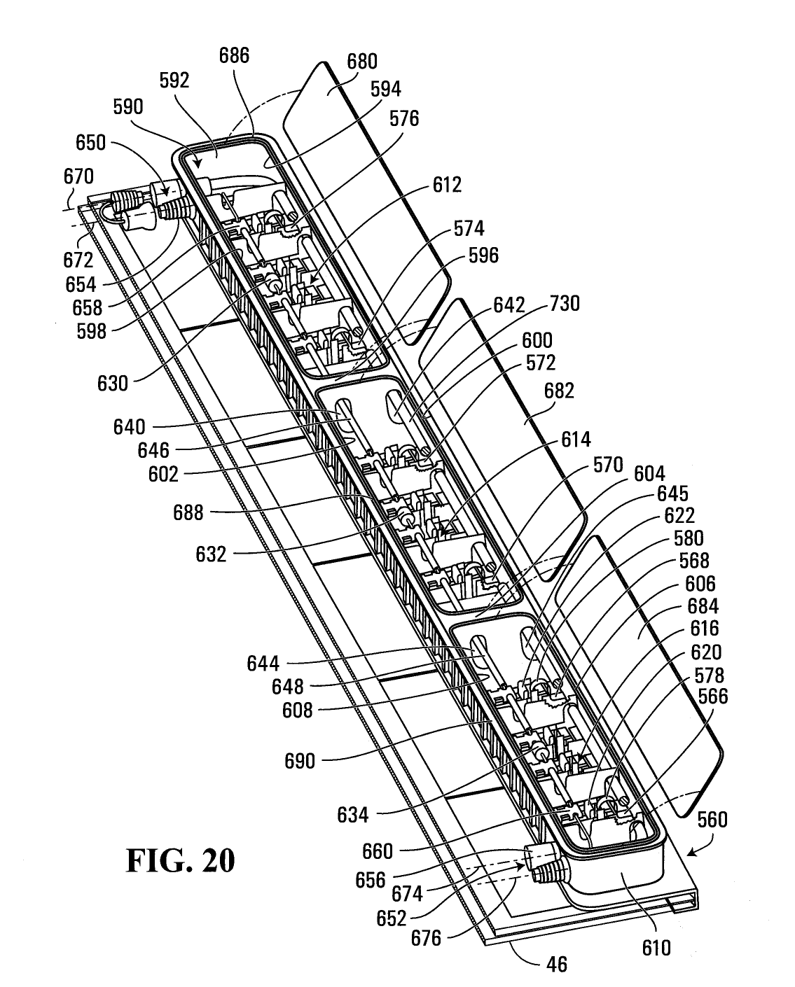

In the embodiment shown in FIG. 19, a unitary electrical connector holder 590 is shown in exploded view but is received on the mounting portion 564 as shown in FIG. 20, for example, or is integral with the mounting portion.

Referring to FIG. 20, the electrical connector holder 590 has a plurality of walls 592, 594, 596, 598, 600, 602, 604, 606, 608, and 610 that define a plurality of compartments, in this embodiment first, second and third compartments 612, 614, and 616, each associated with a respective string of PV cells. The compartments 612, 614, and 616 are disposed about respective pairs of openings and in this embodiment the first compartment 612 is disposed about openings 574 and 576, the second compartment 614 is disposed about openings 570 and 572, and the third compartment 616 is disposed about openings 566 and 568 such that when the terminating portions 578-588 extend through the openings 566-576, they are disposed inside a compartment associated with the corresponding string of PV cells. Thus for example, first and second terminating portions 578 and 580 extend into the third compartment 616 through openings 566 and 568. The third compartment 616 has first and second electrical connectors 620 and 622 to which the first and second terminating portions 578 and 580 are terminated. In general, each compartment comprises a pair of electrical connectors and the positive and negative terminating portions of respective strings of PV cells in the laminate 46 extend through respective openings of the pair of openings associated with the compartment and are connected to the respective pair of electrical connectors associated with the compartment.

In the embodiment shown, bypass diodes such as shown at 630, 632, and 634 are connected between respective connectors of the pairs of electrical connectors associated with respective compartments and thus the bypass diodes are connected across the positive and negative terminating portions of respective strings to thereby protect the respective strings from acting as a current sink in the event the string is shaded.

In the embodiment shown, at least some of the walls defining the compartments have passageways extending between adjacent compartments and in this embodiment walls 596 and 604 have first and second passage ways 640, 642, 644, and 645 respectively. The passage ways 640 and 644 have wires 646 and 648 extending therethrough for connecting the electrical connectors of adjacent compartments together. This facilitates connection of the strings of PV cells in series for example.

Still referring to FIG. 20, the electrical connector holder 590 further includes first and second pairs 650 and 652 respectively of externally accessible electrical connectors. Each pair is on an opposite side of the electrical connector holder 590 and is therefor positioned adjacent a respective side of the laminate 46. One connector of each pair, for example connectors 654 and 656, is connected to the electrical connector 658 and 660 respectively of the first and third compartments 612 and 616 as these connectors act as the positive and negative terminals of the series string of PV cells formed by connecting the cells together using the wires 646 and 648. In the embodiment shown, the first and second pairs 650 and 652 of externally accessible connectors have co-planar connections axes 670, 672, 674, and 676 that extend generally in a plane parallel to a plane of the laminate 46.

Finally, cover members 680, 682, and 684 may be provided to co-operate with flange portions 686, 688, and 690 respectively to seal the first, second and third compartments 612, 614, and 616 respectively to protect the connectors disposed therein and other components disposed therein from weather.

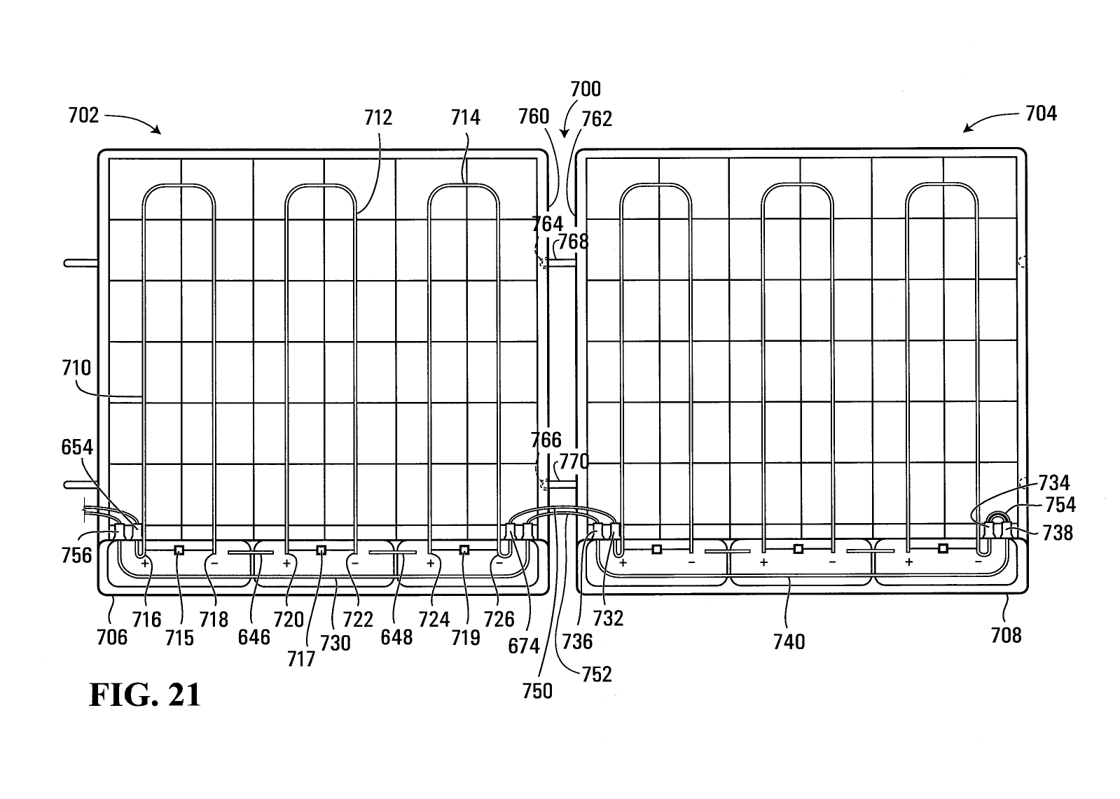

Referring to FIG. 21, two PV modules employing the frame member shown in FIG. 20 are shown generally at 700. A first PV module is shown generally at 702 and a second PV module is shown generally at 704. Both of the first and second PV modules 702 and 704 are fitted with frame members of the type shown at 560 in FIG. 20. For simplicity, these frame members are labeled 706 and 708 respectively. It will be appreciated that the planar view shown illustrates the back sides of the PV modules 702 and 704. First, second and third strings of PV cells of the first PV module are shown generally at 710, 712, and 714 respectively. The positive and negative terminals of each respective string are shown at 716, 718, 720, 722, 724, and 726 and bypass diodes 715, 717, and 719 are connected across respective strings 710, 712, and 714. The strings are connected together by wires 646 and 648 to form a single series string of PV cells having a positive terminal provided by terminal 716 and a negative terminal provided by terminal 726. The positive terminal 716 is connected to a first externally accessible electrical connector 654 and the negative terminal 726 is connected to another externally accessible electrical connector 674. Therefore, from outside of the PV module, externally accessible electrical connector 654 acts as the positive terminal for the PV module and externally accessible electrical connector 674 acts as the negative terminal for the PV module. The remaining connectors of each pair are connected together by a single wire 730.

The second PV module 704 is configured similarly such that it has a positive externally accessible electrical connector 732 and a negative externally accessible electrical connector 734. Again the remaining connectors 736 and 738 are connected together by a single wire 740.

To connect the first and second PV modules together, a first jumper 750 is connected between the externally accessible electrical connector 674 of the first PV module 702 and the externally accessible electrical connector 732 of the second PV module 704. A second jumper 752 is connected between the remaining adjacent connectors to connect wire 730 to wire 740. In addition, a third jumper 754 is connected between the negative terminal 734 of the second PV module 704 and the other terminal 738 to connect the negative terminal of the second PV module, which now acts as the negative terminal of the overall system, to the wires 730 and 740 to cause the externally accessible electrical connector 756 adjacent the externally accessible electrical connector 654 to act as the negative terminal for the overall system. Connector 654 acts as the positive terminal for the overall system. Because all of the externally accessible connectors are disposed to have a connection axis generally parallel to the plane of the laminates of each of the PV modules 702 and 704, the jumpers 750, 752, and 754 generally lie in a plane parallel to the planes of the PV modules thus do not interfere with the positioning of inside edges 760 and 762 of the PV modules, enabling the inside edges to abut each other and eliminating any need to space apart the PV modules in order to remove any one PV module from the system.

If desired, the inside edge 760 of the first PV module 702 may be provided with small receptacles such as shown at 764 and 766 for receiving corresponding projections 768 and 770 for aligning the first and second PV modules 702 and 704 in a common plane. It will be appreciated that the receptacles 764, 766 and projections 768, 770 are just one of a plurality of ways of aligning the first and second PV modules 702 and 704 in a co-planar arrangement.

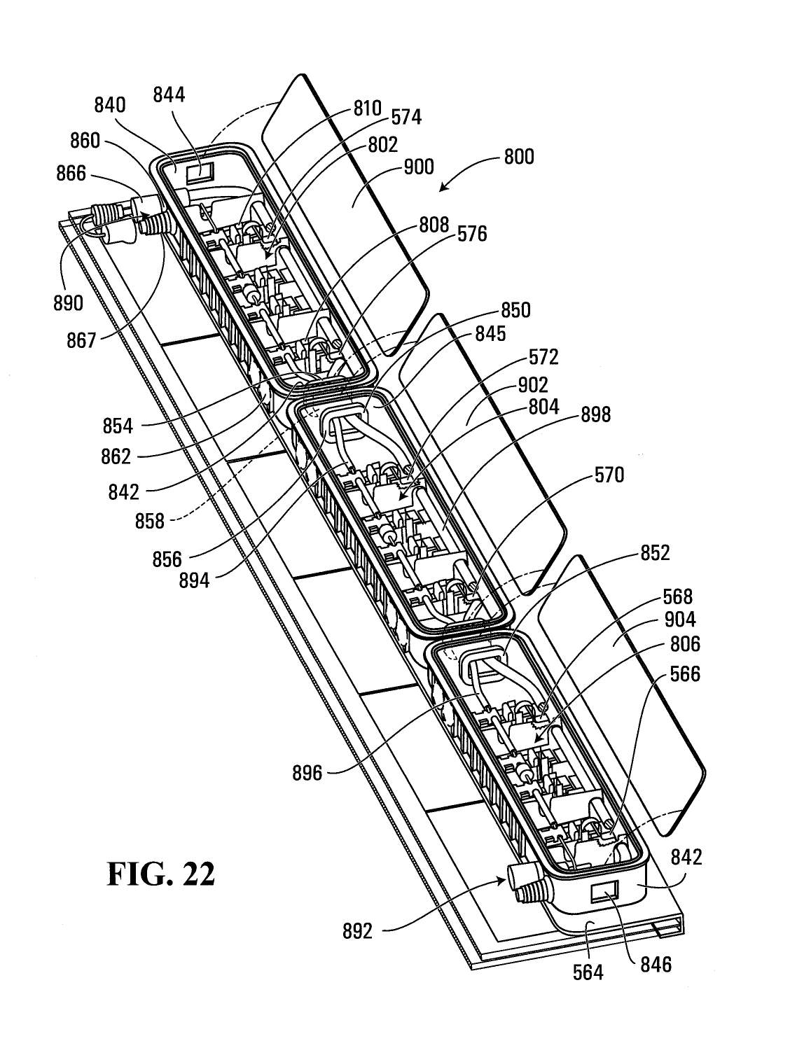

Referring to FIG. 22, a frame member according to an alternative embodiment of the invention is shown generally at 800 and includes the same mounting portion 564 as shown in FIG. 19, however in this embodiment there is provided a plurality of electrical connector holders shown generally at 802, 804, and 806. Each electrical connector holder has a respective pair of electrical connectors 808 and 810, for example and each electrical holder is located over a respective pair of openings in the mounting portion 564. For example the first electrical connector holder is located over openings 574 and 576. The second electrical connector holder is located over openings 570 and 572 and the third electrical connector holder is located over openings 566 and 568. Thus, the respective terminating portions of respective strings of PV cells can extend through respective openings of the pairs of openings into respective electrical connector holders which may be considered to be associated with respective strings of PV cells of the PV module.

In this embodiment, each of the electrical connector holders 802, 804, and 806 has a respective end wall 840 and 842 having a frangible portion 844 and 846 that may be broken out, as desired to provide an opening through the corresponding end wall 840 and 842. This facilitates the insertion of conduits such as shown at 850 and 852 between adjacent electrical connector holders such as between the first and second holders 802 and 804 and the second and third holders 804 and 806.

In the embodiment shown, the conduits are provided by rubber grommets having opposed flanges 854 and 856 disposed at opposite ends of a neck portion 858 whereby the flanges are disposed against inside surfaces of walls 842 and 845 respectively and the neck portion 858 extends through the openings created by breaking the frangible portions 844 and adjacent electrical connector holders. The use of rubber grommets as conduits 850 and 852 facilitates installation of the grommets after the separate electrical connector holders 802, 804, and 806 are fastened to the mounting portion 564 and provide generally weather tight seals that prevent moisture ingress.

The electrical connector holders 802, 804, and 806 may further be provided with frangible portions such as shown at 860 and 862 on opposite ends thereof to facilitate selectively mounting externally accessible electrical connectors such as shown at 866 and 867 in frangible portions 860. The frangible portions 860 can be used on the first electrical connector holder 802 and the frangible portions 862 can be used on the third electrical connector holder 806 to facilitate mounting of the first and second pairs of externally accessible electrical connectors 890 and 892 disposed on opposite sides of the PV module.

Wires such as shown at 894 and 896 act to connect respective strings of PV cells in series and these wires extend through the conduits 850 and 852 between the first and second electrical connector holders 802 and 804 and the second and third electrical connectors 804 and 806 respectively. In addition a wire 898 is connected between one connector of each pair 890 and 892 of the externally accessible electrical connectors to provide for use of the PV module in a manner similar to that depicted in FIG. 21, for example.

Finally, each electrical connector holder 802, 804, and 806 is provided with a respective cover 900, 902, and 904 to provide for generally weather tight sealing of the corresponding electrical connector holders. It will be appreciated that the use of the separate electrical connector holders 802, 804, and 806 in FIG. 22 simplifies the manufacturing process in that a single style of electrical connector holder with frangible portions as shown may be fabricated such as by injection molding plastic to provide one of the indicated electrical connector holders. The same mold can be used to make any number of electrical connector holders of this type and thus any number of electrical holders may be positioned end to end as shown in FIG. 22 to provide for termination of the positive and negative terminating portions of each string of PV cells in the laminate. The frangible portions 844, 846, 860, and 862 can be punched out as needed, depending upon the position of the electrical connector on the frame member.

In each of the embodiments shown herein it will be appreciated that conductors connected to positive and negative terminals of strings of PV cells are brought out through the outer perimeter edge of the laminate with which they are associated and terminated in an electrical connector disposed on a frame member of a frame surrounding the laminate. This eliminates the need for a junction box as is used in the prior art and allows a bypass diode to be mounted at an edge of the PV module. Furthermore, especially where the frame member is made of a heat conductive material, heat generated in the bypass diode is conducted to the electrical connectors which are connected to the frame member, which facilitates dissipation of heat through the frame and any mounting apparatus to which is it connected. This may be contrasted with the dissipation of heat through a junction box mounted on the back of the PV module as in the prior art, where this type of heat dissipation can significantly increase the temperature of the PV cells adjacent the junction box.

While specific embodiments of the invention have been described and illustrated, such embodiments should be considered illustrative of the invention only and not as limiting the invention as construed in accordance with the accompanying claims.

1. A PV module apparatus comprising:
a plurality of PV cells arranged in a planar array having a front side and a back side, said plurality of PV cells being electrically connected together in at least one string having a positive terminal and a negative terminal for supplying electrical energy to a load;
positive and negative conductors connected to said positive and negative terminals respectively;
front and back encapsulating sheets disposed on said front and back sides of said array to form a sub-laminate comprised of said array and said front and back encapsulating sheets, said sub-laminate having a first outer perimeter edge;
each of said positive and negative conductors having a respective portion extending from said positive and negative terminals respectively, between said front and back encapsulating sheets and having first and second terminating portions respectively extending outwardly from said first outer perimeter edge of said sub-laminate; and
front and back protectors disposed on said front and back encapsulating sheets respectively to form a laminate comprising said sub-laminate and said front and back protectors, said front and back protectors having second and third outer perimeter edges respectively generally coterminous with said first outer perimeter edge and defining an outer perimeter edge of said laminate, said first and second terminating portions extending outwardly from said outer perimeter edge of said laminate.

2. The apparatus of claim 1 wherein said first and second terminating portions extend from opposite edge portions of said outer perimeter edge of said laminate.

3. The apparatus of claim 1 wherein said first and second terminating portions extend from a common edge portion of said outer perimeter edge of said laminate.

4. The apparatus of claim 1 wherein said array is electrically connected into a plurality of subset strings, each subset string having a positive terminal and a negative terminal and further comprising conductors disposed entirely between said first and second encapsulating sheets, operably configured to electrically connect said subset strings together, said positive and negative conductors being electrically connected to first and last subset strings of said subset strings that are electrically connected together.

5. The apparatus of claim 1 wherein said array is electrically connected into a plurality of subset strings, each subset string having a positive terminal and a negative terminal and further comprising conductors disposed outside said outer perimeter edge of said laminate operably configured to electrically connect said subset strings together, said positive and negative conductors being electrically connected to first and last subset strings of said subset strings that are electrically connected together.

6. The apparatus of claim 1 further comprising:
a frame surrounding said outer perimeter edge of said laminate, said frame having a holder operably configured to hold electrical connectors, said first and second terminating portions of said positive and negative conductors extending into said holder;
first and second electrical connectors disposed in said holder, said first and second terminating portions being connected to said first and second electrical connectors respectively; and
third and fourth electrical connectors in said holder such that said third and fourth electrical connectors are accessible externally of said holder, said third and fourth electrical connectors being electrically connected to said first and second connectors respectively, to enable said array to be connected to a load.

7. The apparatus of claim 6 wherein said frame comprises a plurality of frame members connected together, wherein each frame member holds a respective portion of said outer perimeter edge of said laminate.

8. The apparatus of claim 7 wherein said frame members have end portions having integral openings therein and further comprising corner connectors operably configured to be received in said integral openings to connect adjacent frame members together.

9. The apparatus of claim 6 wherein at least one of said frame members has a holder for holding a plurality of electrical connectors.

10. The apparatus of claim 9 wherein said array is electrically connected into a plurality of subset strings, each subset string having a positive terminal and a negative terminal and respective conductors extending from said positive and negative terminals said respective conductors each having a terminating portion extending outwardly of said outer perimeter of said laminate and extending into said holder.

11. The apparatus of claim 10 further comprising a plurality of electrical connectors in said holder, said terminating portions of said conductors being connected to respective electrical connectors in said holder.

12. The apparatus of claim 11 further comprising a bypass diode in said holder and electrically connected to a pair of electrical connectors associated with a subset string of PV cells, to protect said subset string of PV cells from excessive electrical current when said subset string is not producing electric current.

13. The apparatus of claim 6 further comprising a protector operably configured to protect said electrical connectors from weather.

14. The apparatus of claim 1 further comprising a frame member having a receptacle and a first opening adjacent said receptacle and in communication with said receptacle, at least a portion of said outer perimeter edge of said laminate being in said receptacle and whereby at least one of said first and second terminating portions extends across a portion of said outer perimeter edge of said laminate and across a portion of a back side of said laminate in said receptacle and extends through said first opening to facilitate connection of said at least one of said first and second terminating portions to an electrical connector adjacent said back side of said laminate and adjacent said outer perimeter edge of said laminate.

15. The apparatus of claim 14 wherein said frame member has a mounting portion, adjacent said receptacle, for mounting an electrical connector holder to said frame member, said mounting portion being disposed generally parallel to said laminate such that when the electrical connector holder is mounted to said mounting portion, said electrical connector holder extends generally outwardly away from said back side of said laminate.

16. The apparatus of claim 15 wherein said first opening is in said mounting portion.

17. The apparatus of claim 16 further comprising an electrical connector holder on said mounting portion, for holding at least one electrical connector, said electrical connector holder being positioned on said mounting portion such that said at least one of said first and second terminating portions can extend through said first opening into said electrical connector holder and into the electrical connector held therein.

18. The apparatus of claim 17 wherein said electrical connector holder is integral with said electrical connector mount.

19. The apparatus of claim 15 wherein said mounting portion has a plurality of openings for receiving corresponding terminating portions.

20. The apparatus of claim 19 further comprising an electrical connector holder comprising a plurality of walls defining a plurality of compartments, said plurality of walls including a bottom wall, said bottom wall having pairs of openings in each compartment, each said pair of openings being disposed about a respective pair of openings of said plurality of openings in said mounting portion, and each compartment comprising a pair of electrical connectors, whereby positive and negative terminating portions of respective strings of PV cells in said laminate extend through respective openings in said mounting portion and through said pair of openings associated with a respective said compartment and wherein said first and second terminating portions are connected to the respective pair of electrical connectors in the compartment associated with the openings through which the first and second terminating portions extend.

21. The apparatus of claim 20 further comprising bypass diodes connected between respective connectors of said pairs of said electrical connectors associated with respective said compartments.

22. The apparatus of claim 21 wherein at least some of said walls have passageways between adjacent compartments.

23. The apparatus of claim 22 wherein said passageways have wires extending therethrough, for connecting the electrical connectors of adjacent compartments.

24. The apparatus of claim 23 wherein said wires connect said electrical connectors of adjacent compartments such that said strings of PV cells are electrically connected in a series string having positive and negative terminals and wherein said apparatus further comprises first and second pairs of externally accessible electrical connectors, each pair being on an opposite side of said electrical connector holder and adjacent a respective side of said laminate, one connector of each pair being electrically connected together, and one connector of each pair being connected to a respective one of said positive and negative terminals of said series string of PV cells.

25. The apparatus of claim 24 wherein said first and second pairs of externally accessible connectors have coplanar connection axes that extend generally in a plane parallel to a plane of said laminate.

26. The apparatus of claim 15 wherein said mounting portion has a plurality of openings therein for receiving respective terminating portions of respective strings of PV cells within said laminate therethrough.

27. The apparatus of claim 26 further comprising a plurality of electrical connector holders on said mounting portion, each electrical connector holder having a respective pair of electrical connectors and each electrical connector holder being located over a respective pair of openings in said mounting portion to enable said respective terminating portions of respective strings of PV cells to extend through respective openings of said pairs of openings, into respective electrical connector holders for connection to said electrical connectors therein.

28. The apparatus of claim 27 wherein said electrical connector holders have end walls with end openings therein and wherein conduits extend between end openings of adjacent electrical connector holders.

29. The apparatus of claim 28 further comprising wires extending through said conduits to electrically connect said electrical connectors in adjacent electrical connector holders.

30. The apparatus of claim 29 wherein said wires connect said electrical connectors of adjacent electrical connector holders such that said strings of PV cells are electrically connected in a series string having positive and negative terminals and wherein said apparatus further comprises first and second pairs of externally accessible electrical connectors, each pair being on respective electrical connector holders on opposite sides of said laminate, one connector of each pair being electrically connected together, and one connector of each pair being connected to a respective one of said positive and negative terminals of said series string of PV cells.

31. The apparatus of claim 30 wherein said first and second pairs of externally accessible connectors have coplanar connection axes that extend generally in a plane parallel to a plane of said laminate.

32. A frame apparatus for a PV module, the apparatus comprising:
an elongate body having first and second opposite ends and a module holder between said first and second opposite ends, said module holder being operably configured to hold an edge portion of an outer perimeter edge of the PV module;
first and second frame connectors disposed at said first and second ends respectively, said first and second frame connectors being operably configured to receive and hold a frame connector element operably configured to connect two adjacent said frame members together;
an electrical connector holder adjacent said module holder, operably configured to hold at least one electrical connector;
an opening extending between said module holder and said electrical connector holder, said opening being operably configured to receive therethrough at least one conductor extending from the outer perimeter edge of the PV module such that the at least one conductor can extend from the outer perimeter edge of the PV module into the module holder and from the module holder into an electrical connector in the electrical connector holder, in a continuous curve.

33. The apparatus of claim 32 wherein said elongate body includes first and second parallel spaced apart walls forming said module holder and third and fourth parallel spaced apart walls forming said electrical connector holder, said first and second parallel spaced apart walls extending in a direction opposite to said third and fourth parallel spaced apart walls.

34. The apparatus of claim 33 wherein said body comprises an inner wall between said first and second parallel spaced apart walls and said third and fourth spaced apart walls, said first and second parallel spaced apart walls and said third wall defining an edge space in which a portion of the outer perimeter edge portion of the PV module can be received and said third and fourth parallel spaced apart walls and said inner wall defining an electrical connector space in which at least one electrical connector may be mounted, said opening being disposed in said inner wall.

35. The apparatus of claim 33 further comprising first and second transverse walls extending between said third and fourth walls, said third and fourth parallel spaced apart walls further defining said electrical connector space.

36. The apparatus of claim 35 further comprising first and second connector mounts on said first and second transverse walls respectively operably configured to mount first and second electrical connectors to said first and second transverse walls respectively.

37. The apparatus of claim 35 further comprising a removable cover operably configured to cooperate with said third and fourth walls and said first and second transverse walls to enclose said electrical connector space.

38. A frame apparatus for a PV module comprising a laminate having an outer perimeter edge and at least first and second terminating conductors extending from said outer perimeter edge, the apparatus comprising:
a frame member having a receptacle and a first opening adjacent said receptacle and in communication with said receptacle,
at least a portion of said outer perimeter edge of said laminate being in said receptacle and at least one of said first and second terminating conductors extending across a portion of said outer perimeter edge of said laminate and across a portion of a back side of said laminate, in said receptacle; and
wherein said at least one of said first and second terminating portions extends through said first opening to facilitate connection of said at least one of said first and second terminating conductors to an electrical connector adjacent said back side of said laminate and adjacent said outer perimeter edge of said laminate.

39. The apparatus of claim 38 wherein said frame member has a mounting portion, adjacent said receptacle, for mounting an electrical connector holder to said frame member, said mounting portion being disposed generally parallel to said laminate such that when the electrical connector holder is mounted to said mounting portion, said electrical connector holder extends generally outwardly away from the back side of said laminate.

40. The apparatus of claim 39 wherein said first opening is in said mounting portion.

41. The apparatus of claim 40 further comprising an electrical connector holder on said mounting portion, for holding at least one electrical connector, said electrical connector holder being positioned on said mounting portion such that said at least one of said first and second terminating conductors can extend through said first opening into said electrical connector holder and into the electrical connector held therein.

42. The apparatus of claim 41 wherein said electrical connector holder is integral with said electrical connector mount.

43. The apparatus of claim 39 wherein said mounting portion has a plurality of openings for receiving respective terminating conductors.

44. The apparatus of claim 43 further comprising an electrical connector holder comprising a plurality of walls defining a plurality of compartments, said plurality of walls including a bottom wall, said bottom wall having pairs of openings in each compartment, each said pair of openings being disposed about a respective pair of openings of said plurality of openings in said mounting portion, and each compartment comprising a pair of electrical connectors, whereby positive and negative terminating conductor of respective strings of PV cells in said laminate extend through respective openings in said mounting portion and into a respective said compartment and wherein said first and second terminating conductors are connected to the respective pair of electrical connectors in the compartment associated with the openings through which the first and second terminating portions extend.

45. The apparatus of claim 44 further comprising bypass diodes connected between respective connectors of said pairs of said electrical connectors associated with respective said compartments.

46. The apparatus of claim 45 wherein at least some of said walls have passageways between adjacent compartments.

47. The apparatus of claim 46 wherein said passageways have wires extending therethrough, for connecting the electrical connectors of adjacent compartments.

48. The apparatus of claim 47 wherein said wires connect said electrical connectors of adjacent compartments such that said strings of PV cells are electrically connected in a series string having positive and negative terminals and wherein said apparatus further comprises first and second pairs of externally accessible electrical connectors, each pair being on an opposite side of said electrical connector holder and adjacent a respective edge of said laminate, one connector of each pair being electrically connected together, and one connector of each pair being connected to a respective one of said positive and negative terminating conductors of said series string of PV cells.

49. The apparatus of claim 48 wherein said first and second pairs of externally accessible connectors have coplanar connection axes that extend generally in a plane parallel to a plane of said laminate.

50. The apparatus of claim 39 wherein said mounting portion has a plurality of openings therein for receiving respective terminating conductors of respective strings of PV cells within said laminate therethrough.

51. The apparatus of claim 50 further comprising a plurality of electrical connector holders on said mounting portion, each electrical connector holder having a respective pair of electrical connectors and each electrical connector holder being located over a respective pair of openings in said mounting portion to enable said respective terminating conductors portions of respective strings of PV cells to extend through respective openings of said pairs of openings, into respective electrical connector holders for connection to said electrical connectors therein.

52. The apparatus of claim 51 wherein said electrical connector holders have end walls with end openings therein and wherein conduits extend between end openings of adjacent electrical connector holders.

53. The apparatus of claim 52 further comprising wires extending through said conduits to electrically connect said electrical connectors in adjacent electrical connector holders.

54. The apparatus of claim 53 wherein said wires connect said electrical connectors of adjacent electrical connector holders such that said strings of PV cells are electrically connected in a series string having positive and negative terminating conductors and wherein said apparatus further comprises first and second pairs of externally accessible electrical connectors, each pair being on respective electrical connector holders on opposite edges of said laminate, one connector of each pair being electrically connected together, and one connector of each pair being connected to a respective one of said positive and negative terminating conductors of said series string of PV cells.

55. The apparatus of claim 54 wherein said first and second pairs of externally accessible connectors have coplanar connection axes that extend generally in a plane parallel to a plane of said laminate.

56. A frame system for a PV module, the system comprising:
a plurality of frame members, operably configured to surround and hold an outer perimeter edge of the PV module, each frame member comprising:
an elongate body having first and second opposite ends and a module holder between said first and second opposite ends, said module holder being operably configured to hold a respective edge portion of the outer perimeter edge of the PV module;
first and second frame connectors disposed at said first and second ends respectively, said first and second frame connectors being operably configured to receive and hold a frame connector element operably configured to connect two adjacent said frame members together;
at least one of said plurality of frame members further comprising:
an electrical connector holder adjacent said module holder, operably configured to hold at least one electrical connector;
an opening extending between said module holder and said electrical connector holder, said opening being operably configured to receive therethrough at least one conductor extending from the outer perimeter edge of the PV module such that the at least one conductor can extend from the outer perimeter edge of the PV module into the module holder and from the module holder into an electrical connector in the electrical connector holder, in a continuous curve.

57. A method for making a PV module apparatus of claim 1, the method comprising:
arranging a plurality of PV cells in a planar array, said planar array having a front side and a back side;
electrically connecting said plurality of PV cells together in at least one string having a positive terminal and a negative terminal;
connecting positive and negative conductors to said positive and negative terminals respectively;
affixing front and back encapsulating sheets on said front and back sides respectively of said array, to form a sub-laminate comprised of said planar array and said front and back encapsulating sheets, said sub-laminate having a first outer perimeter edge, said front and back encapsulating sheets being affixed such that each of said positive and negative conductors has a respective portion extending from said positive and negative terminals respectively, between said front and back encapsulating sheets and such that first and second terminating portions of said positive and negative conductors respectively extend outwardly from said first outer perimeter edge of said sub-laminate to facilitate connection to said positive and negative conductors to an external circuit; and
affixing front and back protectors on opposite sides of said sub-laminate to form a laminate comprising said sub-laminate and said front and back protectors, said front and back protectors having second and third outer perimeter edges respectively generally coterminous with said first outer perimeter edge and defining an outer perimeter edge of said laminate, said first and second terminating portions extending outwardly from said outer perimeter edge of said laminate.

58. The method of claim 57 further comprising causing said first and second terminating portions to extend from opposite edge portions of said outer perimeter edge of said laminate.

59. The method of claim 57 further comprising causing said first and second terminating portions to extend from a common edge portion of said outer perimeter edge of said laminate.

60. The method of claim 57 further comprising electrically connecting subsets of said array of PV cells into separate subset strings, each subset string having a positive terminal and a negative terminal and causing said subset strings to be electrically connected together by respective conductors disposed entirely between said first and second encapsulating sheets, said positive and negative conductors being electrically connected to first and last subset strings of said subset strings that are electrically connected together.

61. The method of claim 57 further comprising electrically connecting subsets of said array of PV cells into separate subset strings, each subset string having a positive terminal and a negative terminal and causing said subset strings to be electrically connected together by respective conductors disposed outside said outer perimeter edge of said laminate, said positive and negative conductors being electrically connected to first and last subset strings of said subset strings that are electrically connected together.

62. The method of claim 57 further comprising:
surrounding said outer perimeter edge of said laminate with a frame having an integral holder operably configured to hold first and second electrical connectors;
causing said first and second terminating portions of said positive and negative conductors to extend into said holder, and connecting said first and second terminating portions to said first and second electrical connectors respectively; and
connecting said first and second electrical connectors to third and fourth electrical connectors on said holder, said third and fourth electrical connectors having portions externally of said holder to enable said array to be electrically connected to a load.

63. The method of claim 62 wherein surrounding said laminate with a frame comprises connecting a plurality of frame members together such that each of said frame members holds a respective portion of said outer perimeter edge of said laminate.

64. The method of claim 63 wherein connecting said plurality of frame members together comprises corner connectors with openings integrally formed in respective said frame members.

65. The method of claim 62 further comprising:
electrically connecting subsets of said array of PV cells into separate subset strings, each subset string having a positive terminal and a negative terminal;
connecting each positive and negative terminal of each string to a respective conductor having a respective terminating portion extending into said holder; and
connecting respective said terminating portions of said conductors to a respective electrical connector disposed in said holder.

66. The method of claim 62 further comprising installing a bypass diode in said holder and electrically connecting said bypass diode to a pair of electrical connectors associated with a subset string of PV cells to protect said subset string of PV cells from excessive electrical current when said subset string is not generating electric current.

67. The method of claim 62 further comprising protecting said electrical connectors in said holder from weather.

68. The method of claim 57 further comprising:
a) bending at least one of said first and second terminating portions to extend across a portion of said outer perimeter edge of said laminate and across a portion of a back side of said laminate;
b) receiving said portion of said outer perimeter edge of said laminate in a receptacle of a frame member having a first electrical connector such that said at least one of said first and second terminating portions extends through an opening in said frame member to facilitate connection of said at least one of said first and second terminating portions to said first electrical connector when said outer perimeter edge of said laminate is fully received in said receptacle; and
c) connecting said at least one of said first and second terminating portions to said electrical connector.

69. The method of claim 68 further comprising holding said first electrical connector in a holder on said frame member.

70. The method of claim 69 wherein holding said first electrical connector comprises holding said first electrical connector in a holder disposed on said frame member to extend away from said back side of said laminate when said outer perimeter edge of said laminate is received in said receptacle.

71. The method of claim 69 further comprising connecting said first electrical connector to a second electrical connector having at least a portion extending out of said holder to facilitate connection of said second electrical connector to a load.

72. A method of framing a PV module, the method comprising:
surrounding and holding an outer perimeter edge of the PV module with a plurality of frame members,
wherein surrounding comprises connecting said frame members together by receiving portions of frame connector elements in respective frame connectors of adjacent frame members and
wherein holding comprises causing module holders extending between first and second opposite end portions of respective frame members to hold respective edge portions of the outer perimeter edge of the PV module; and
causing at least one conductor extending from an outer perimeter edge of the PV module to extend into said module holder of one of said plurality of frame members and into an electrical connector disposed in an electrical connector holder on an outer portion of said one of said plurality of frame members.

73. The method of claim 72 wherein causing comprises causing said at least one conductor to extend in a continuous curve from said outer edge of said PV module to said electrical connector.

74. The method of claim 73 further comprising connecting said electrical connector to an externally accessible terminal mounted on said one of said plurality of frame members to enable the PV module to be connected to a load.

75. The method of claim 74 further comprising covering said electrical connector holder to protect said electrical connectors from weather.

76. The method of claim 72 wherein causing comprises causing a plurality of conductors extending from an outer perimeter edge of the PV module to extend into said module holder of one of said plurality of frame members and into respective electrical connectors disposed in an electrical connector holder on an outer portion of said one of said plurality of frame members.

77. The method of claim 76 further comprising connecting said respective electrical connectors to respective externally accessible terminals mounted on said one of said plurality of frame members to enable the PV module to be connected to a load.

78. The method of claim 76 further comprising installing a bypass diode in said electrical connector holder and connecting said bypass diode to two adjacent electrical connectors to provide for current bypassing of a string of PV cells in the PV module.

79. The method of claim 78 further comprising covering said electrical connector holder to protect said electrical connectors and said bypass diode from weather.
